(19) United States
(12) Patent Application Publication
(10) Pub. No.: US 2024/0260268 A1
(43) Pub. Date: Aug. 1, 2024

(54) THREE-DIMENSIONAL MEMORY DEVICE CONTAINING INVERTED STAIRCASE AND METHOD OF MAKING THE SAME

(71) Applicant: SANDISK TECHNOLOGIES LLC, ADDISON, TX (US)

(72) Inventors: Takayuki MAEKURA, Yokkaichi (JP); Yoshitaka OTSU, Yokkaichi (JP)

(21) Appl. No.: 18/357,676

(22) Filed: Jul. 24, 2023

Related U.S. Application Data
(60) Provisional application No. 63/482,105, filed on Jan. 30, 2023.

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80006; H01L 2224/80895; H01L 2224/80896; H01L 2924/1431; H01L 2924/14511

(57) ABSTRACT

A device structure includes an alternating stack of insulating layers and composite layers located over a source layer, where each of the composite layers includes a combination of a respective dielectric material layer and a respective electrically conductive layer, memory openings vertically extending through the alternating stack, memory opening fill structures located in the memory openings, where each of the memory opening fill structures includes a respective vertical stack of memory elements and a respective vertical semiconductor channel, and contact via structures vertically extending through a respective subset of the dielectric material layers and the insulating layers in the alternating stack and contacting a horizontal surface of a respective one of the electrically conductive layers in the alternating stack.

### FIELD

The present disclosure relates generally to the field of semiconductor devices, and particularly to a three-dimensional memory device including inverted staircase and contact via structures and methods for forming the same.

### BACKGROUND

A three-dimensional memory device including a three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36. Support circuitry for performing write, read, and erase operations of the memory cells in the vertical NAND strings typically are provided by complementary metal oxide semiconductor (CMOS) devices formed on a same substrate as the three-dimensional memory device.

### SUMMARY

According to an aspect of the present disclosure, a device structure is provided, which comprises: an alternating stack of insulating layers and composite layers located over a source layer, wherein each of the composite layers includes a combination of a respective dielectric material layer and a respective electrically conductive layer; memory openings vertically extending through the alternating stack; memory opening fill structures located in the memory openings, wherein each of the memory opening fill structures comprises a respective vertical stack of memory elements and a respective vertical semiconductor channel; and contact via structures vertically extending through a respective subset of the dielectric material layers and the insulating layers in the alternating stack and contacting a horizontal surface of a respective one of the electrically conductive layers in the alternating stack.

According to another aspect of the present disclosure, a method of forming a device structure comprises: forming an alternating stack of insulating layers and sacrificial material layers comprising a dielectric material over a carrier substrate; forming memory openings through the alternating stack; forming memory opening fill structures in the memory openings, wherein each of the memory opening fill structures comprises a respective vertical stack of memory elements and a respective vertical semiconductor channel; forming lateral isolation trenches and access via cavities in the alternating stack, wherein each of the sacrificial material layers is exposed to each of the lateral isolation trenches, and the access via cavities have different depths; forming lateral recesses by isotropically recessing the sacrificial material layers around the lateral isolation trenches and the access via cavities, wherein the lateral extents of the lateral recesses are different, and wherein remaining portions of the sacrificial material layers comprise dielectric material layers; forming electrically conductive layers in the lateral recesses; forming lateral isolation trench fill structures and via-fill pillar structures in the lateral isolation trenches and the access via cavities, respectively; forming contact via cavities through a respective subset of the dielectric material layers and through a respective subset of the insulating layers onto a horizontal surface of a respective one of the electrically conductive layers; and forming contact via structures in the contact via cavities in contact with the electrically conductive layers.

### BRIEF DESCRIPTION OF THE DRAWINGS

FIG. 1 is a schematic vertical cross-sectional view of an exemplary structure after formation of a source-level insulating layer, a source layer, and an alternating stack of insulating layers and sacrificial material layers over a carrier substrate according to an embodiment of the present disclosure.

FIG. 2A is a vertical cross-sectional view of the exemplary structure after formation of support pillar structures and support wall structures according to an embodiment of the present disclosure.

FIG. 2B is a top-down view of the exemplary structure of FIG. 2A. The vertical plane A-A′ is the plane of the vertical cross-section of FIG. 2A.

FIG. 2C is a zoom-out top-down view of the exemplary structure of FIGS. 2A and 2B. The vertical plane A-A′ is the plane of the vertical cross-section of FIG. 2A.

FIG. 3A is a vertical cross-sectional view of the exemplary structure after formation of memory openings according to an embodiment of the present disclosure.

FIG. 3B is a top-down view of the exemplary structure of FIG. 3A. The vertical plane A-A′ is the plane of the vertical cross-section of FIG. 3A.

FIG. 3C is a zoom-out top-down view of the exemplary structure of FIGS. 3A and 3B. The vertical plane A-A′ is the plane of the vertical cross-section of FIG. 3A.

FIGS. 4A-4F are sequential schematic vertical cross-sectional views of a memory opening within the exemplary structure during formation of a memory opening fill structure therein according to an embodiment of the present disclosure.

FIG. 5A is a vertical cross-sectional view of the exemplary structure after formation of memory opening fill structures according to an embodiment of the present disclosure.

FIG. 5B is a top-down view of the exemplary structure of FIG. 5A. The vertical plane A-A′ is the plane of the vertical cross-section of FIG. 5A.

FIG. 5C is a zoom-out top-down view of the exemplary structure of FIGS. 5A and 5B. The vertical plane A-A′ is the plane of the vertical cross-section of FIG. 5A.

FIG. 6A is a vertical cross-sectional view of the exemplary structure after formation of a patterned hard mask according to an embodiment of the present disclosure.

FIG. 6B is a top-down view of the exemplary structure of FIG. 6A. The vertical plane A-A′ is the plane of the vertical cross-section of FIG. 6A.

FIG. 6C is a zoom-out top-down view of the exemplary structure of FIGS. 6A and 6B. The vertical plane A-A′ is the plane of the vertical cross-section of FIG. 6A.

FIGS. 7A-7E are sequential vertical cross-sectional views of the exemplary structure during formation of lateral isolation trenches and access via trenches according to an embodiment of the present disclosure.

FIG. 8A is a vertical cross-sectional view of the exemplary structure after formation of lateral recesses according to an embodiment of the present disclosure.

FIG. 8B is a top-down view of the exemplary structure of FIG. 8A. The vertical plane A-A′ is the plane of the vertical cross-section of FIG. 8A.

FIG. 8C is a zoom-out top-down view of the exemplary structure of FIGS. 8A and 8B. The vertical plane A-A′ is the plane of the vertical cross-section of FIG. 8A.

FIG. 8D is a vertical cross-sectional view of the exemplary structure along the vertical plane D-D′ of FIGS. 8B, 8C, 8F and 8G.

FIG. 8E is another vertical cross-sectional view of the exemplary structure along the vertical plane A-A′ of FIG. 8A in which a location of an omitted region in the view is laterally shifted relative to the view of FIG. 8A.

FIG. 8F is a horizontal cross-sectional view of exemplary structure along the horizontal plane F-F′ in FIGS. 8A, 8D, and 8E.

FIG. 8G is a horizontal cross-sectional view of exemplary structure along the horizontal plane G-G′ in FIGS. 8A, 8D, and 8E.

FIG. 9A is a vertical cross-sectional view of the exemplary structure after formation of electrically conductive layers in the lateral recesses according to an embodiment of the present disclosure.

FIG. 9B is a top-down view of the exemplary structure of FIG. 9A. The vertical plane A-A′ is the plane of the vertical cross-section of FIG. 9A.

FIG. 9C is a zoom-out top-down view of the exemplary structure of FIGS. 9A and 9B. The vertical plane A-A′ is the plane of the vertical cross-section of FIG. 9A.

FIG. 9D is a vertical cross-sectional view of the exemplary structure along the vertical plane D-D′ of FIGS. 9B, 9C, 9F and 9G.

FIG. 9E is another vertical cross-sectional view of the exemplary structure along the vertical plane A-A′ of FIG. 9A in which a location of an omitted region in the view is laterally shifted relative to the view of FIG. 9A.

FIG. 9F is a horizontal cross-sectional view of exemplary structure along the horizontal plane F-F′ in FIGS. 9A, 9D, and 9E.

FIG. 9G is a horizontal cross-sectional view of exemplary structure along the horizontal plane G-G′ in FIGS. 9A, 9D, and 9E.

FIG. 10A is a vertical cross-sectional view of the exemplary structure after formation of lateral isolation trench fill structures and via-fill pillar structures according to an embodiment of the present disclosure.

FIG. 10B is a top-down view of the exemplary structure of FIG. 10A. The vertical plane A-A′ is the plane of the vertical cross-section of FIG. 10A.

FIG. 10C is a zoom-out top-down view of the exemplary structure of FIGS. 10A and 10B. The vertical plane A-A′ is the plane of the vertical cross-section of FIG. 10A.

FIG. 10D is a vertical cross-sectional view of the exemplary structure along the vertical plane D-D′ of FIGS. 10B and 10C.

FIG. 11 is a vertical cross-sectional view of the exemplary structure after formation of metal interconnect structures and memory-side bonding pads according to an embodiment of the present disclosure.

FIG. 12 is a vertical cross-sectional view of the exemplary structure after bonding a logic die to a memory die according to an embodiment of the present disclosure.

FIG. 13 is a vertical cross-sectional view of the exemplary structure after removal of the carrier substrate according to an embodiment of the present disclosure.

FIG. 14A is a vertical cross-sectional view of the exemplary structure after formation of layer contact via structures and source contact via structures according to an embodiment of the present disclosure.

FIG. 14B is horizontal cross-sectional view of the exemplary structure along the horizontal plane B-B′ of FIG. 14A. The vertical plane A-A′ is the plane of the vertical cross-section of FIG. 14A.

FIG. 15 is a vertical cross-sectional view of the exemplary structure after formation of backside metal interconnect structures and backside bonding pads according to an embodiment of the present disclosure.

FIGS. 16A, 16B, 16C, 16D and 16E are sequential vertical cross-sectional views of steps during fabrication of an alternative exemplary structure according to an alternative embodiment of the present disclosure.

### DETAILED DESCRIPTION

As discussed above, the embodiments of the present disclosure are directed to a three-dimensional memory device including inverted staircase and contact via structures and methods for forming the same, the various aspects of which are described below. The embodiments of the present disclosure can be used to form various structures including a multilevel memory structure, non-limiting examples of which include semiconductor devices such as three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition. Unless otherwise indicated, a “contact” between elements refers to a direct contact between elements that provides an edge or a surface shared by the elements. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “prototype” structure or an “in-process” structure refers to a transient structure that is subsequently modified in the shape or composition of at least one component therein. As used herein, a first electrical component is electrically connected to a second electrical component if there exists an electrically conductive path between the first electrical component and the second electrical component.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that can be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of dies therein. Each die includes one or more planes. Identical concurrent operations can be executed in each plane within a same die, although there may be some restrictions. In case a die is a memory die, i.e., a die including memory elements, concurrent read operations, concurrent write operations, or concurrent erase operations can be performed in each plane within a same memory die. Each plane contains a number of memory blocks (or “blocks”), which are the smallest unit that can be erased by in a single erase operation. Each memory block contains a number of pages, which are the smallest units that can be selected for programming.

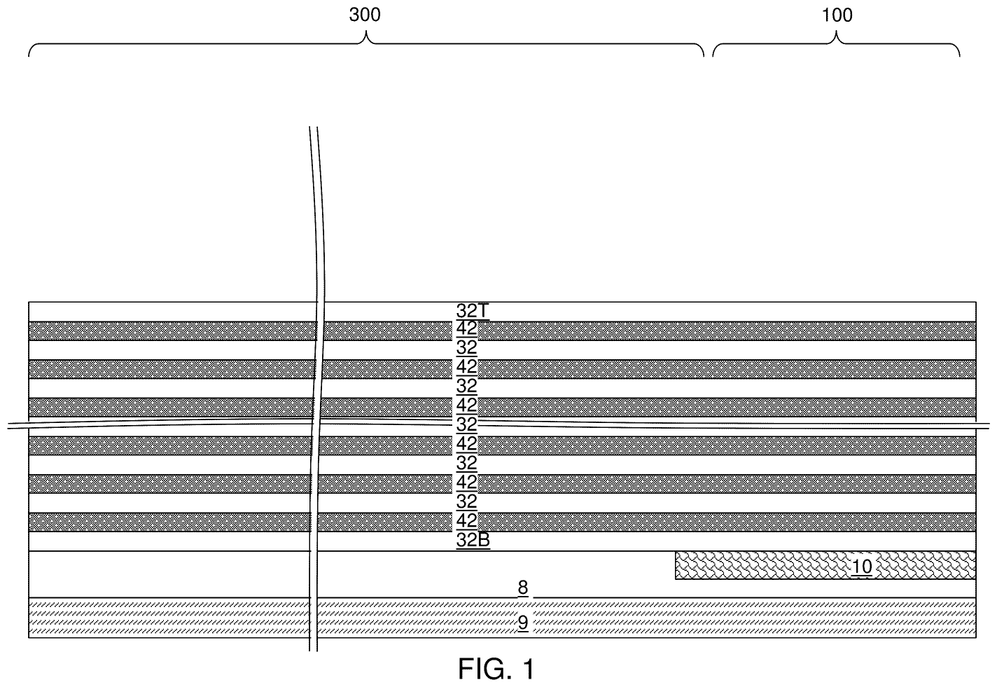

Referring to FIG. 1, an exemplary structure according to an embodiment of the present disclosure is illustrated, which comprises a carrier substrate 9, a source-level insulating layer 8, a source layer 10, and an alternating stack (32, 46) of insulating layers 32 and sacrificial material layers 42. The carrier substrate 9 may comprise any substrate that can be employed to provide structural support during formation of a memory die thereupon. For example, the carrier substrate 9 may comprise a semiconductor substrate, an insulating substrate, a conductive substrate, or a combination thereof. In one embodiment, the carrier substrate 9 may comprise a commercially available single crystalline silicon wafer. The source-level insulating layer 8 comprises an insulating material. For example, the source-level insulating layer 8 may comprise silicon oxide, and may have a thickness in a range from 50 nm to 1,000 nm, although lesser and greater thicknesses may also be employed.

The source layer 10 is formed in or on an upper portion of a source-level insulating layer 8. In one embodiment, the source-level insulating layer 8 may embed the source layer 10. The source layer 10 comprises heavily doped semiconductor material (such as polysilicon, a silicon-germanium alloy, or a III-V compound semiconductor material) having a doping of an opposite conductivity type relative to the conductivity type of vertical semiconductor channels to be subsequently formed. If the vertical semiconductor channels have a doping of a first conductivity type, the source layer 10 may have a doping of a second conductivity type that is the opposite of the first conductivity type. If the first conductivity type is p-type, the second conductivity type is n-type, and vice versa. The atomic concentration of dopants of the second conductivity type in the source layer 10 may be in a range from 5.0×10¹⁸/cm³ to 2.0×10²¹/cm³, such as from 1.0×10¹⁹/cm³ to 1.0×10²¹/cm³, although lesser and greater atomic concentrations may also be employed. The thickness of the source layer 10 may be in a range from 100 nm to 500 nm, although lesser and greater thicknesses may also be employed. In one embodiment, the top surface of the source layer 10 may be formed within a horizontal plane including a top surface of the source-level insulating layer 8.

An alternating stack of insulating layers 32 and sacrificial material layers 42 are formed over the source layer 10. The insulating layers 32 comprise an insulating material such as a silicon-oxide-based insulating material. As used herein, a silicon-oxide-based insulating material refers to an insulating material including undoped silicate glass, a doped silicate glass, organosilicate glass, or silicon oxynitride with, or without, dopants therein. The bottommost layer of the insulating layers 32 is herein referred to as a bottommost insulating layer 32B. The topmost layer of the insulating layers 32 is herein referred to as a topmost insulating layer 32T.

The insulating layers 32 comprise, and/or consist essentially of, the insulating material. Insulating materials that may be used for the insulating layers 32 include, but are not limited to silicon oxide (including doped or undoped silicate glass), silicon oxynitride, organosilicate glass (OSG), spin-on dielectric materials, etc. In one embodiment, the insulating layers 32 may consist essentially of a silicon oxide such as undoped silicate glass or a doped silicate glass.

The sacrificial material layers 42 comprise a sacrificial material that can be removed selective to the insulating material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material. Non-limiting examples of the sacrificial material include silicon nitride, borosilicate glass, organosilicate glass, and a polymer material. In one embodiment, the sacrificial material layers 42 can include silicon nitride.

The insulating layers 32 and the sacrificial material layers 42 can be deposited, for example, by chemical vapor deposition (CVD). The thicknesses of the insulating layers 32 and the sacrificial material layers 42 can be in a range from 20 nm to 50 nm, although lesser and greater thicknesses can be employed for each insulating layer 32 and for each sacrificial material layer 42. The number of repetitions of the pairs of an insulating layer 32 and a sacrificial material layer 42 can be in a range from 2 to 1,024, and typically from 8 to 256, although a greater number of repetitions can also be employed.

The exemplary structure may comprise a memory array region 100 in which memory stack structures are to be subsequently formed, and at least one contact region 300 in which contact via structures are to be subsequently formed.

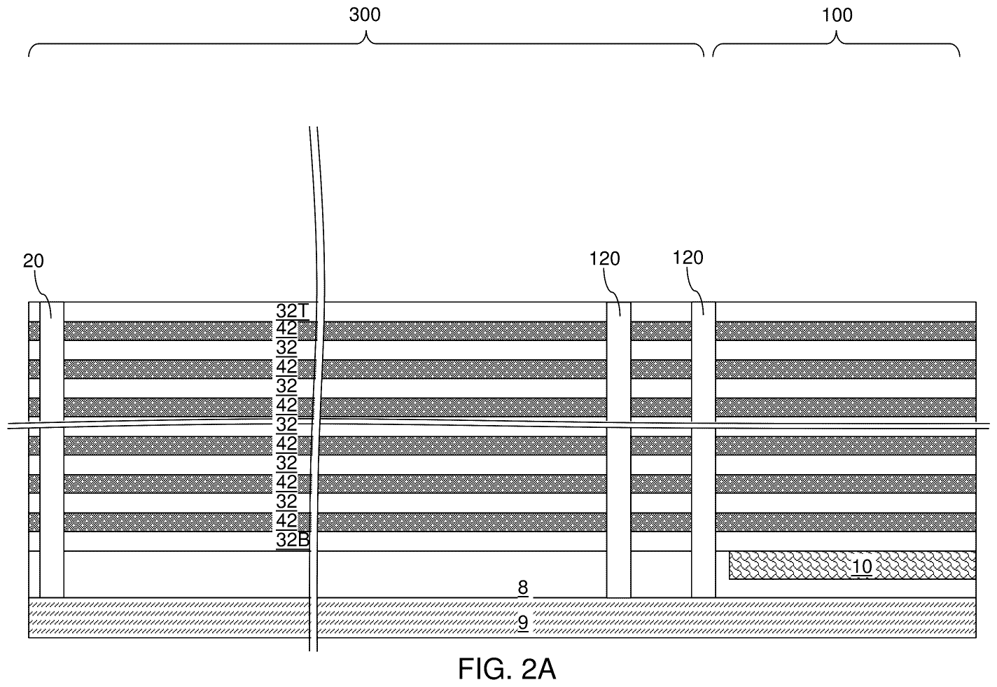

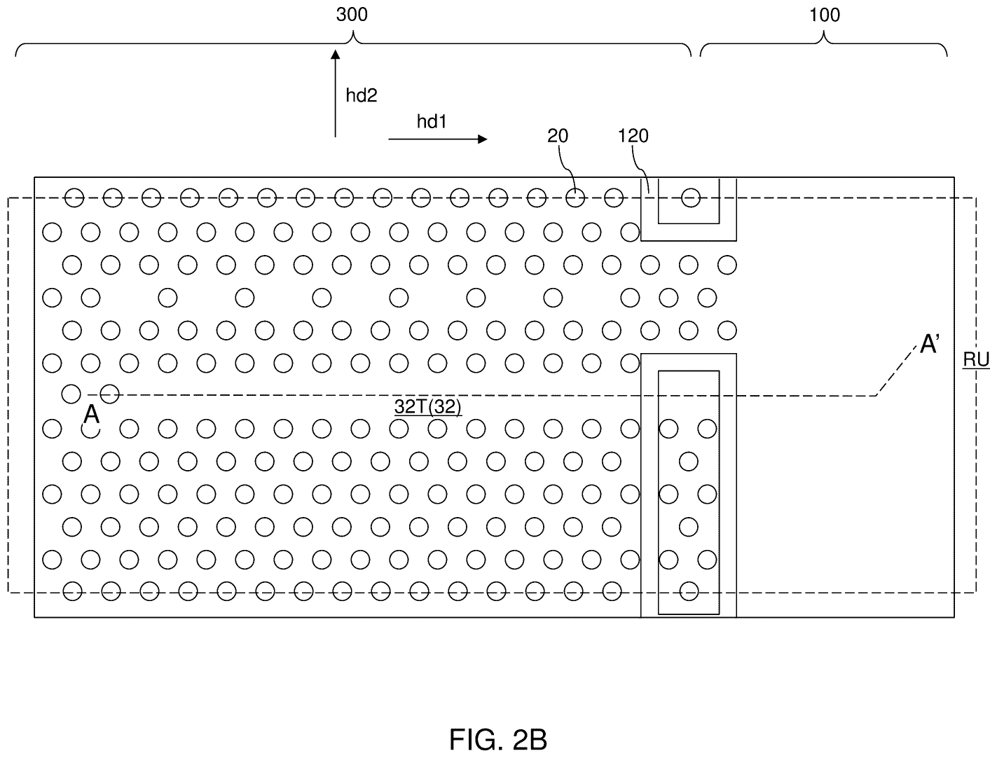

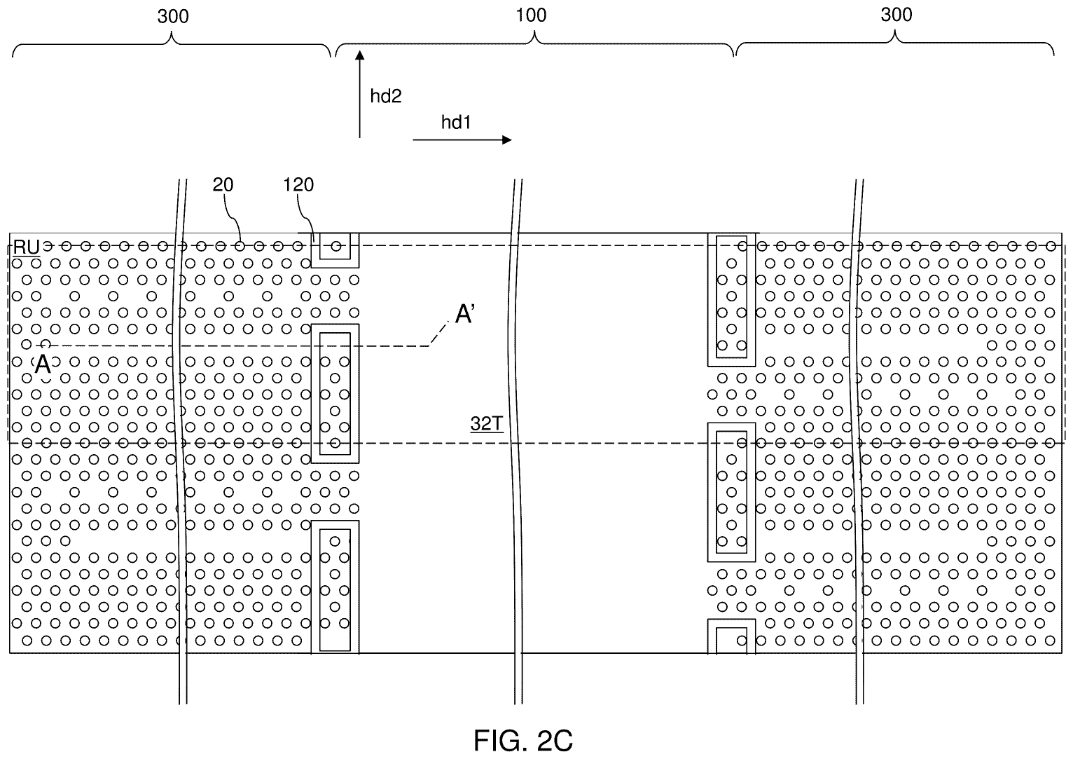

Referring to FIGS. 2A-2C, a lithographic material stack (not shown) including at least a photoresist layer can be formed over the topmost insulating layer 32T, and can be lithographically patterned to form openings therein. The openings include discrete circular or oval-shaped openings that are formed the contact region 300, and elongated openings that are formed adjacent to a boundary between the memory array region 100 and a contact region 300. In one embodiment, the elongated openings comprise moat-shaped openings having respective pair of widthwise opening segments that laterally extend along a first horizontal direction (e.g., word line direction) hd1 and a respective pair of lengthwise opening segments that laterally extend along a second horizontal direction (e.g., bit line direction) hd2. In another embodiment, the elongated openings comprise slit shaped openings.

The pattern in the lithographic material stack can be transferred through the alternating stack (32, 42) and the source-level insulating layer 8 by at least one anisotropic etch that employs the patterned lithographic material stack as an etch mask. Portions of the alternating stack (32, 42) and the source-level insulating layer 8 underlying the openings in the patterned lithographic material stack are etched to form support openings and support trenches. The carrier substrate 9 may be employed as an etch stop structure. As used herein, a “support opening” refers to an opening in which a support structure (such as a support pillar structure) that mechanically supports other elements is subsequently formed. The support openings may comprise cylindrical or rectangular shaped openings. As used herein, a “support trench” refers to trench in which a trench shaped support structure (such as a trench shaped wall structure) that mechanically supports other elements is subsequently formed. The support trench may comprise a linear elongated trench, a curved elongated trench or a moat-shaped trench which encloses a portion of the alternating stack (32, 42). The trench shaped support structure may comprise a linear wall, a curved wall or a moat-shaped wall which encloses a portion of the alternating stack (32, 42)

A dielectric fill material such as undoped silicate glass (i.e., silicon oxide) or a doped silicate glass can be deposited in the support openings and the support trenches by a conformal deposition process, such as a low pressure chemical vapor deposition process. Excess portions of the dielectric fill material can be removed from above the horizontal plane including the top surface of the topmost insulating layer 32T. For example a recess etch process may be employed. Remaining portions of the dielectric fill material that fill the support openings constitute support pillar structures 20. Remaining portions of the dielectric fill material that fill the support moat trenches constitute support wall structures 120. Each of the support pillar structures 20 and the support wall structures 120 may consist essentially of at least one dielectric fill material. Each of the support pillar structures 20 may have a respective horizontal cross-sectional shape of a circle, an oval or a square, and the support wall structures 120 may have a respective shape of a linear wall, a curved wall or rectangular wall frame which may optionally have a rounded corners.

The support pillar structures 20 and the support wall structures 120 may be formed as periodic structures having a periodicity along the second horizontal direction hd2. In this case, a unit pattern including a set of support pillar structures 20 and the set of support wall structures 120 may be repeated along the second horizontal direction hd2. Each repeating unit pattern of the structure is herein referred to as a repetition unit RU. According to an aspect of the present disclosure, each of the support wall structures 120 may have a length along the second horizontal direction hd2 that is the less than the width of the repetition unit RU along the second horizontal direction hd2. In one embodiment, the support pillar structures 20 and the support wall structures 120 may contact a top surface of the carrier substrate 9. In one embodiment, the support pillar structures 20 and the support wall structures 120 may have top surfaces that are coplanar with the top surface of the topmost insulating layer 32T.

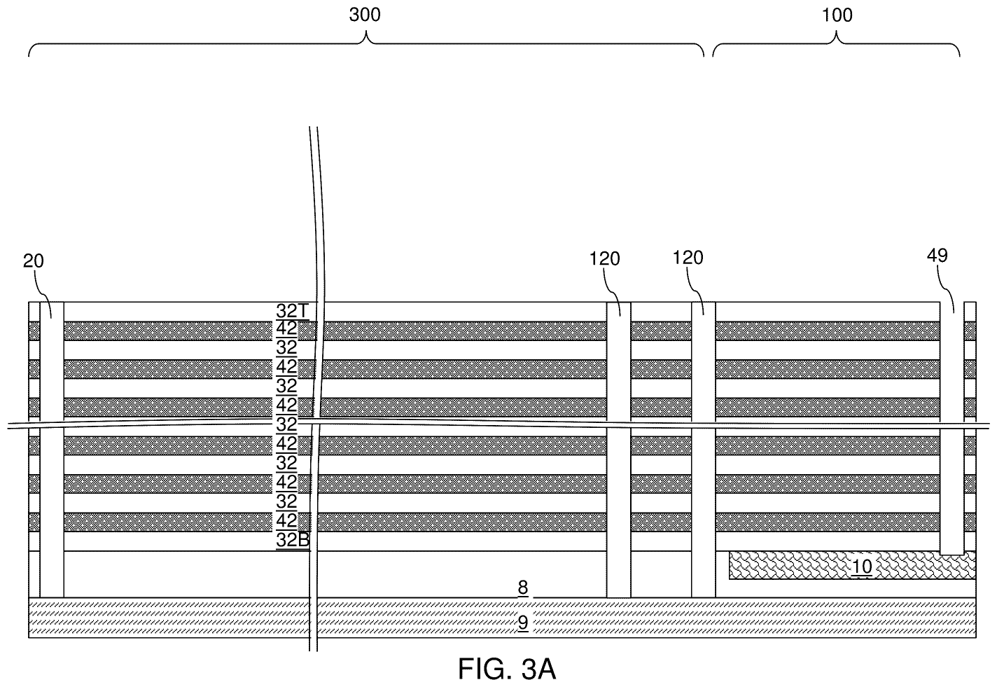

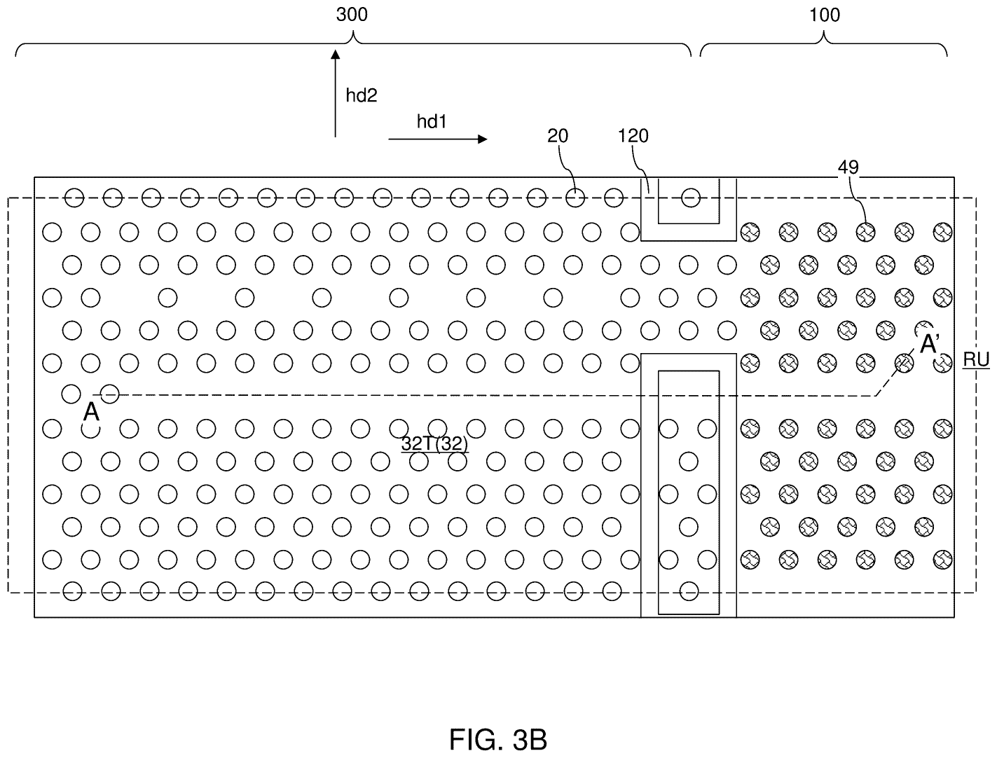

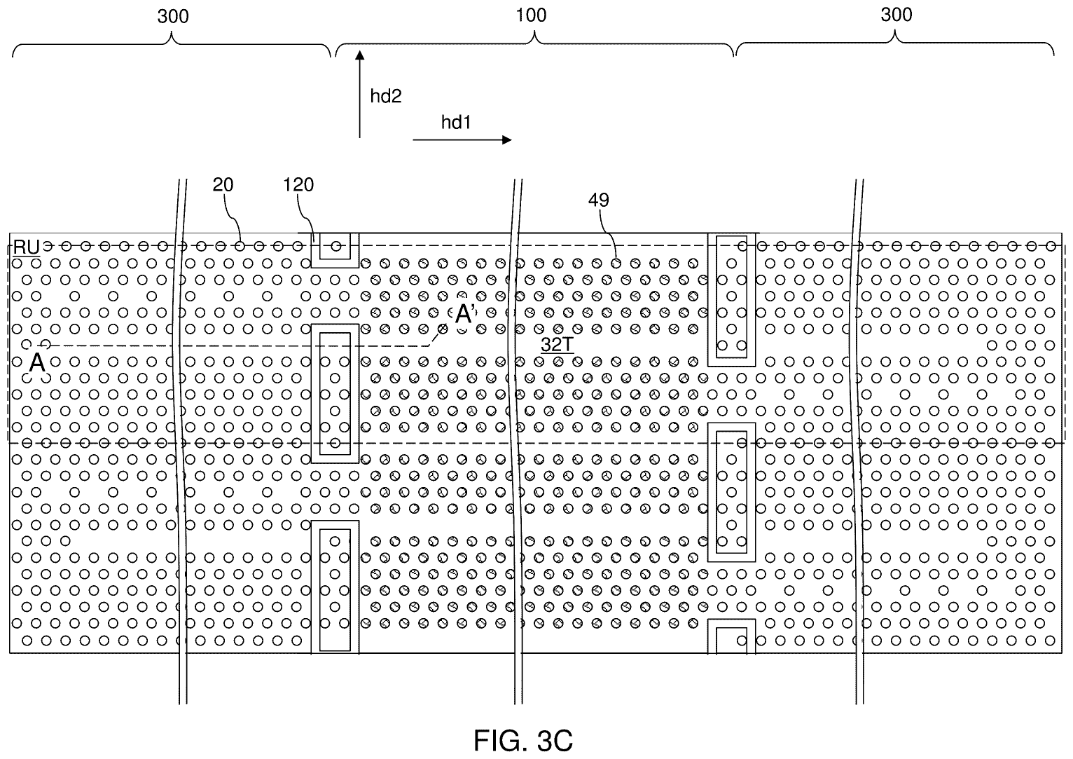

Referring to FIGS. 3A-3C, a lithographic material stack (not shown) including at least a photoresist layer can be formed over the topmost insulating layer 32T, and can be lithographically patterned to form openings therein. The openings include discrete openings that are formed the memory array region 100 within an area in which the source layer 10 is present. In one embodiment, clusters of openings may be formed in as a two-dimensional periodic array of openings that is formed within a respective repetition unit RU.

The pattern in the lithographic material stack can be transferred through the alternating stack (32, 42) and at least to the top surface of the source layer 10 by at least one anisotropic etch that employs the patterned lithographic material stack as an etch mask. Portions of the alternating stack (32, 42) underlying the openings in the patterned lithographic material stack are etched to form memory openings. As used herein, a “memory opening” refers to a structure in which memory elements, such as a memory stack structure, is subsequently formed.

The memory openings 49 extend through the entirety of the alternating stack (32, 42). The chemistry of the anisotropic etch process employed to etch through the materials of the alternating stack (32, 42) can alternate to optimize etching of the materials in the alternating stack (32, 42). The anisotropic etch can be, for example, a series of reactive ion etches. The sidewalls of the memory openings 49 can be substantially vertical, or can be tapered. The patterned lithographic material stack can be subsequently removed, for example, by ashing. In one embodiment, the memory openings 49 can extend from the top surface of the alternating stack (32, 42) to at least the horizontal plane including the topmost surface of the source layer 10. In one embodiment, an overetch into the source layer 10 may be optionally performed after the top surface of the source layer 10 is physically exposed at a bottom of each memory opening 49. The overetch may be performed prior to, or after, removal of the lithographic material stack. In other words, the recessed surfaces of the source layer 10 may be vertically offset from the un-recessed top surfaces of the source layer 10 by a recess depth. The recess depth can be, for example, in a range from 1 nm to 50 nm, although lesser and greater recess depths can also be employed. The overetch is optional, and may be omitted. If the overetch is not performed, the bottom surfaces of the memory openings 49 can be coplanar with the topmost surface of the source layer 10.

A two-dimensional array of memory openings 49 can be formed in the memory array region 100. A plurality of rows of memory openings 49 can be formed such that each row of memory openings 49 is arranged along a first horizontal direction hd1. The plurality of rows of memory openings 49 may be laterally spaced apart along a second horizontal direction hd2 that is perpendicular to the first horizontal direction hd1.

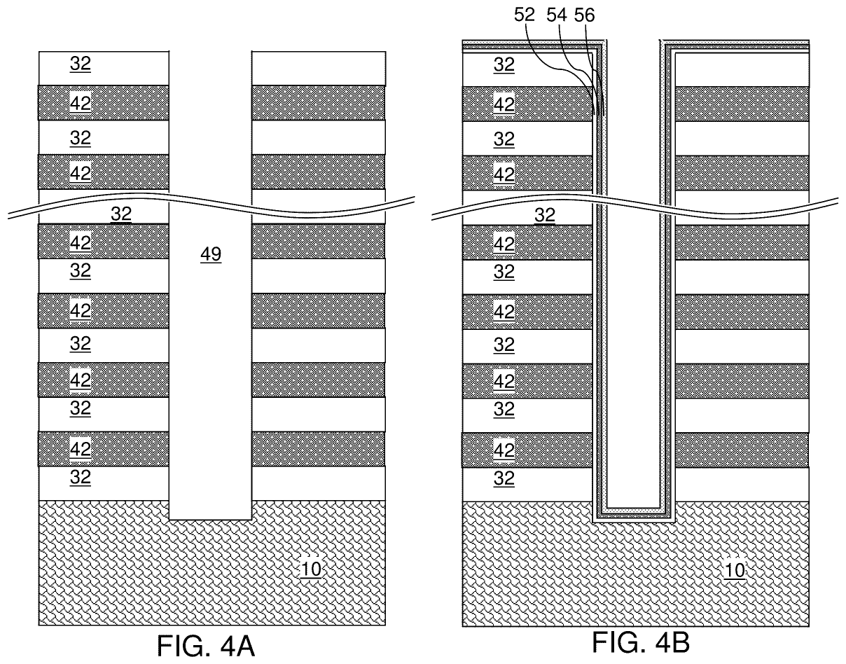

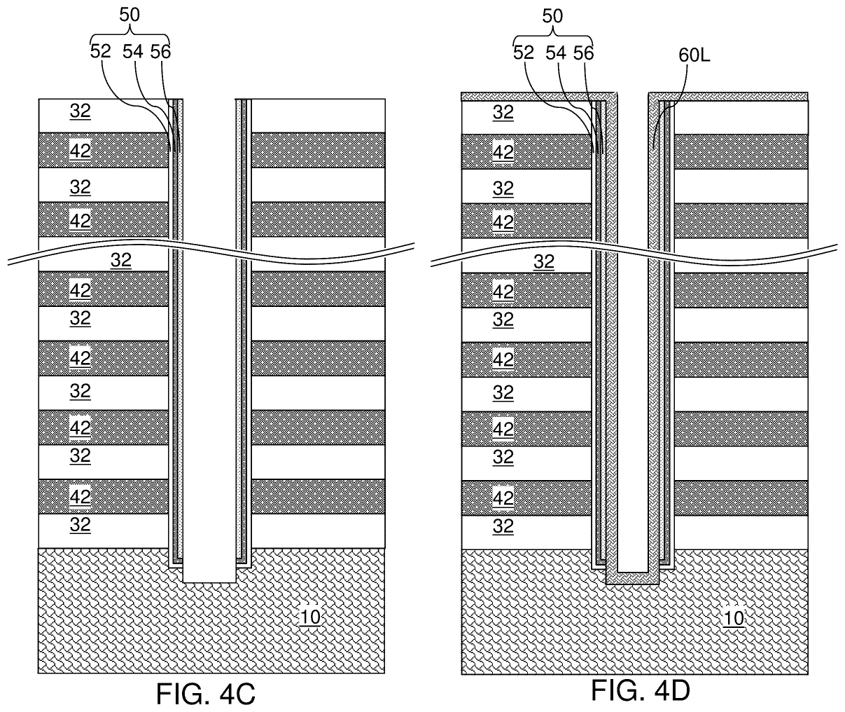

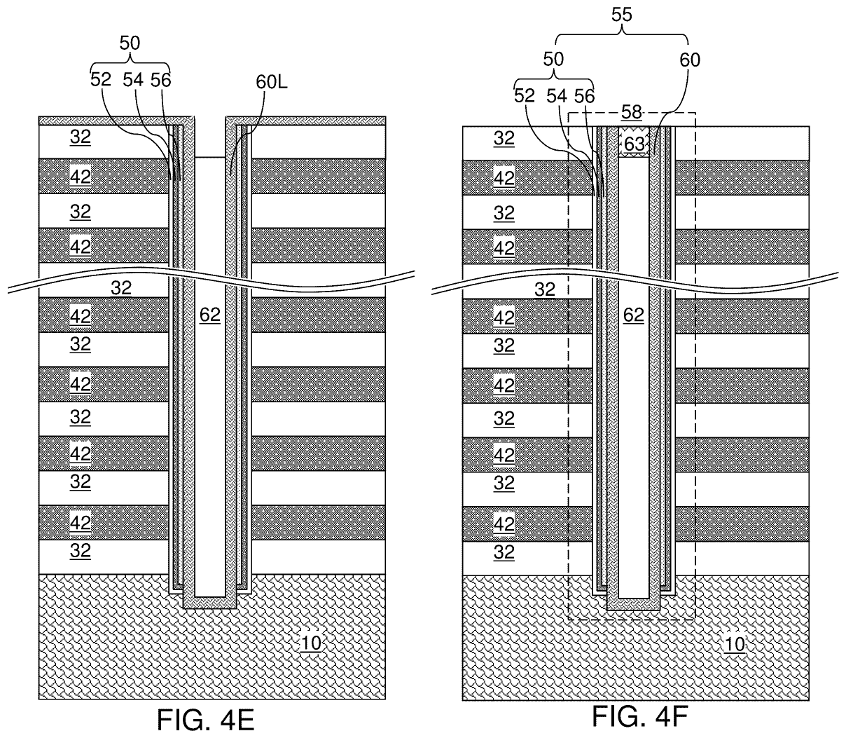

FIGS. 4A-4F are sequential schematic vertical cross-sectional views of a memory opening 49 within the exemplary structure during formation of a memory opening fill structure 58 therein according to an embodiment of the present disclosure.

Referring to FIG. 4A, a memory opening 49 is illustrated after the processing steps described with reference to FIGS. 3A-3C.

Referring to FIG. 4B, a set of material layers can be conformally deposited, which may include an optional blocking dielectric layer 52, a memory material layer 54, and an optional dielectric liner 56. The blocking dielectric layer 52 may comprise at least one blocking dielectric material such as silicon oxide and/or a dielectric metal oxide. The memory material layer 54 may comprise any memory material that can store memory bits therein. For example, the memory material layer 54 may comprise a charge storage layer, such as a silicon nitride layer. Alternatively, the memory material layer 54 may comprise a ferroelectric memory material, a resistive memory material, a phase change memory material, or any other memory material known in the art. In some embodiments, the memory material layer 54 may comprise a vertical stack of discrete memory material portions that are formed at levels of the sacrificial material layers 42. Generally, the memory material layer 54 may comprise a vertical stack of memory elements that are formed at the levels of the sacrificial material layers 42. In one embodiment, the vertical stack of memory elements comprises portions of the memory material layer 54 located at the levels of the sacrificial material layers 42. The optional dielectric liner 56, if present, can provide electrical isolation between the memory material layer 54 and a semiconductor channel to be subsequently formed. In case the memory material layer 54 comprises a charge storage material, the optional dielectric liner 56 may comprise a tunneling dielectric layer.

Referring to FIG. 4C, an anisotropic etch process may be performed to remove horizontally-extending portions of the optional blocking dielectric layer 52, the memory material layer 54, and the optional dielectric liner 56. The combination of vertically-extending portions of the optional blocking dielectric layer 52, the memory material layer 54, and the optional dielectric liner 56 that remain in a respective memory opening 49 constitutes a memory film 50.

Referring to FIG. 4D, a semiconductor channel layer 60L can be deposited over the memory films 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can be formed by a conformal deposition method such as low pressure chemical vapor deposition (LPCVD). In one embodiment, the semiconductor channel layer 60L can be deposited as an amorphous semiconductor material. The thickness of the semiconductor channel layer 60L can be in a range from 2 nm to 10 nm, although lesser and greater thicknesses can also be used. A memory cavity is formed in the volume of each memory opening 49 that is not filled with the deposited material layers (52, 54, 56, 60L).

Referring to FIG. 4E, a dielectric core layer can be deposited to fill any remaining portion of the memory cavity within each memory opening. The dielectric core layer includes a dielectric material, such as silicon oxide or organosilicate glass. The dielectric core layer can be deposited by a conformal deposition method such as low pressure chemical vapor deposition (LPCVD), or by a self-planarizing deposition process such as spin coating. The dielectric core layer can be subsequently recessed selective to the material of the semiconductor channel layer 60L, for example, by a recess etch. The material of the dielectric core layer is vertically recessed below the horizontal plane including the top surface of the topmost insulating layer 32T. Each remaining portion of the dielectric core layer constitutes a dielectric core 62.

Referring to FIG. 4F, a doped semiconductor material having a doping of a second conductivity type can be deposited within each recess cavity located above the dielectric cores 62. The second conductivity type is the opposite of the first conductivity type. For example, if the first conductivity type is p-type, the second conductivity type is n-type, and vice versa. In one embodiment, the doped semiconductor material may be deposited as an amorphous semiconductor material. The dopant concentration in the doped semiconductor material having a doping of the second conductivity type can be in a range from 5.0×10¹⁸/cm³ to 2.0×10²¹/cm³, although lesser and greater dopant concentrations can also be used.

A planarization process can be performed to remove portions of the doped semiconductor material having a doping of the second conductivity type and the semiconductor channel layer 60L from above the top surface of the topmost insulating layer 32T, for example, by chemical mechanical planarization (CMP) or a recess etch to form drain regions 63. Each remaining portion of the semiconductor material having a doping of the second conductivity type constitutes a drain region 63. Each remaining portion of the semiconductor channel layer 60L constitutes a vertical semiconductor channel 60. Electrical current can flow through each vertical semiconductor channel 60 when a vertical NAND device including the vertical semiconductor channel 60 is turned on. Within each memory opening 49, a dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours. Each combination of a memory film 50 and a vertical semiconductor channel 60 constitutes a memory stack structure 55.

Each contiguous combination of a vertical semiconductor channel 60 and a memory film 50 constitutes a memory stack structure 55. Thus, each memory stack structure 55 can include a vertical semiconductor channel 60, a dielectric liner 56, a plurality of memory elements comprising portions of the memory material layer 54, and an optional blocking dielectric layer 52. Each combination of a memory stack structure 55, a dielectric core 62, and a drain region 63 within a memory opening 49 is herein referred to as a memory opening fill structure 58. Generally, each of the memory opening fill structures 58 comprises a respective vertical stack of memory elements (comprising portions of the memory material layer 54), and a respective vertical semiconductor channel 60. In one embodiment, each of the memory opening fill structures 58 comprises a respective drain region 63 contacting a top end of the respective vertical semiconductor channel 60.

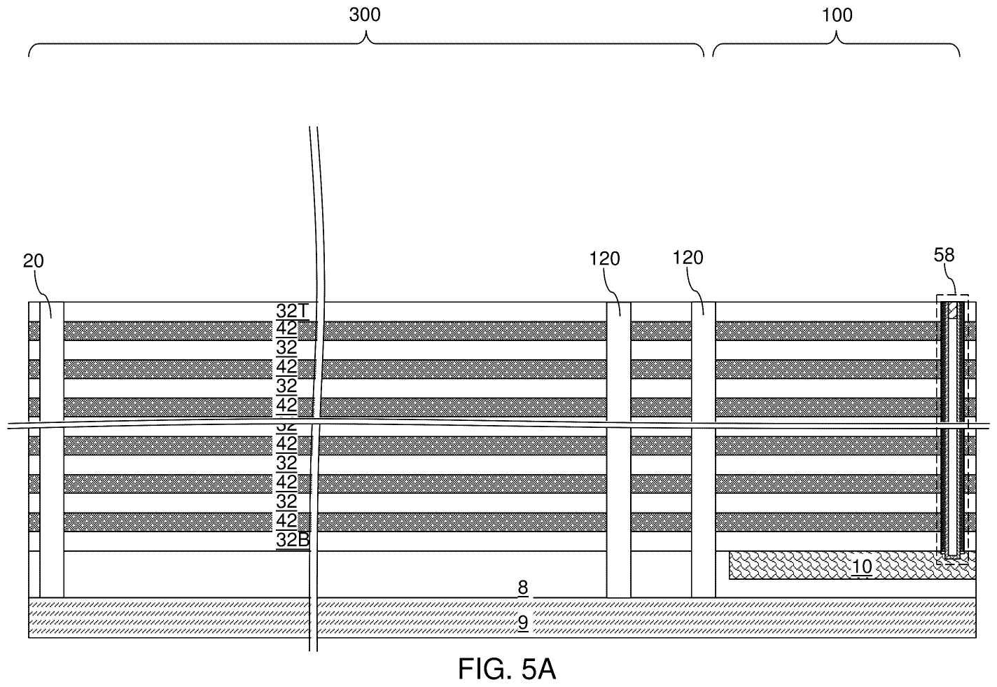

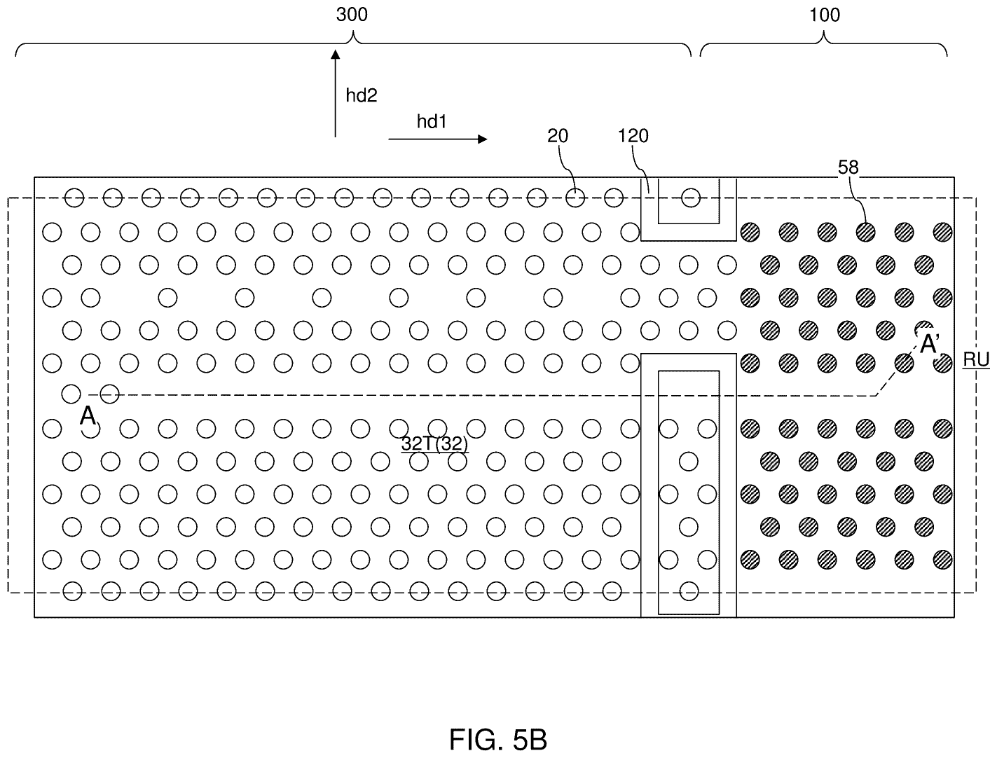

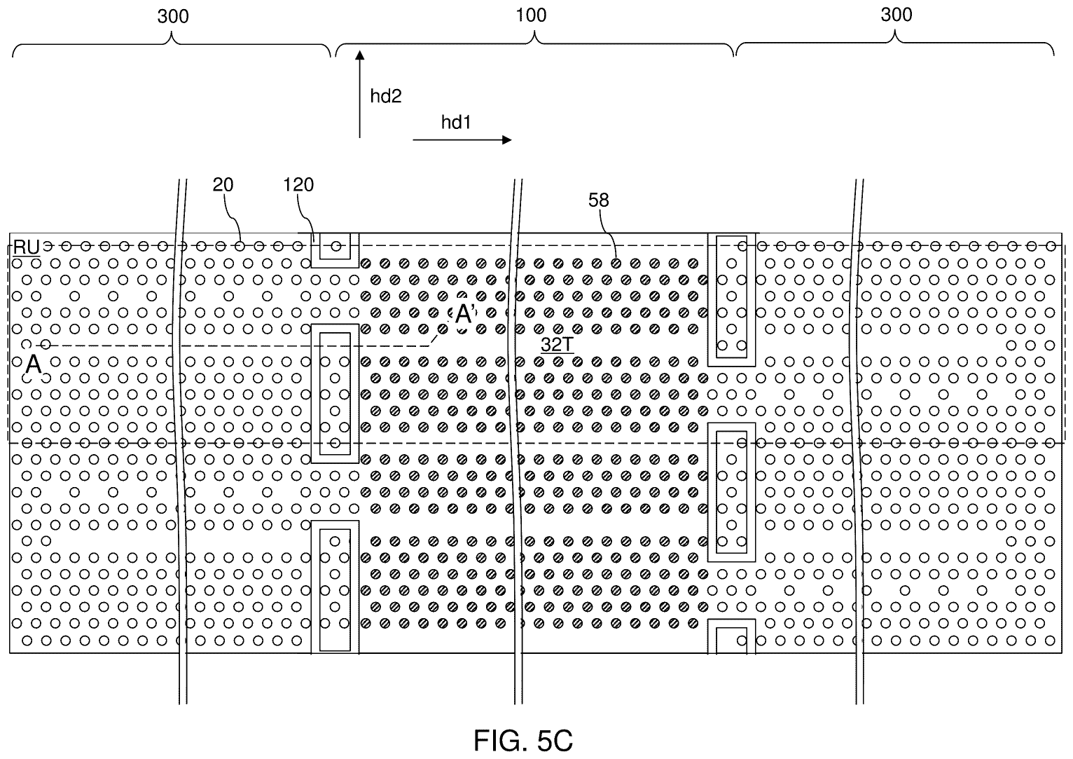

Referring to FIGS. 5A-5C, the exemplary structure is illustrated after formation of memory opening fill structures 58 within the memory openings 49. An instance of a memory opening fill structure 58 can be formed within each memory opening 49 of the structure of FIGS. 3A-3C.

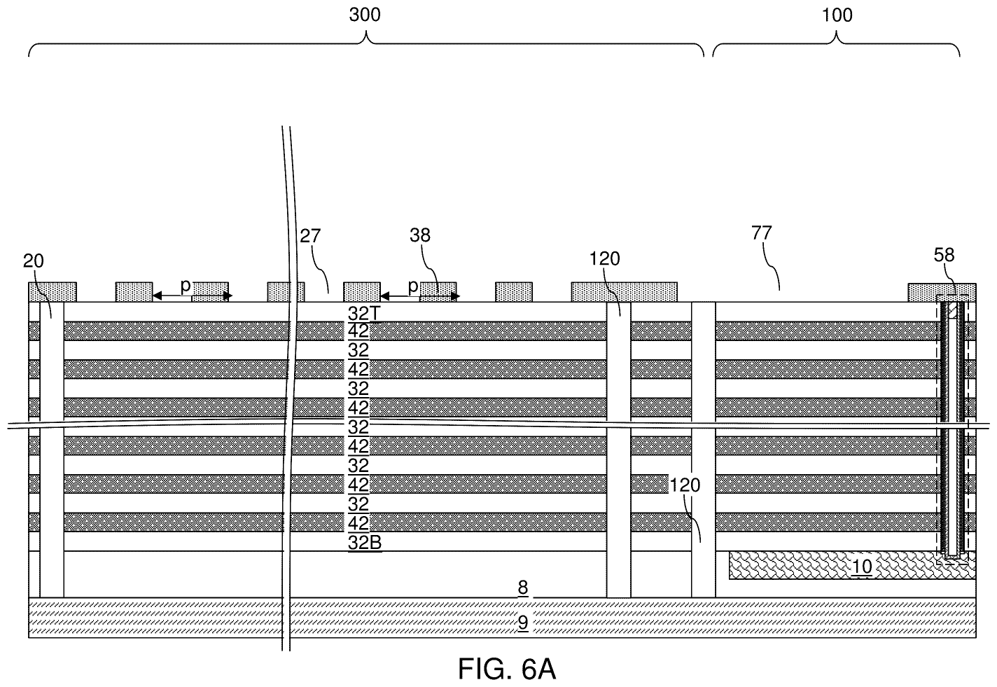

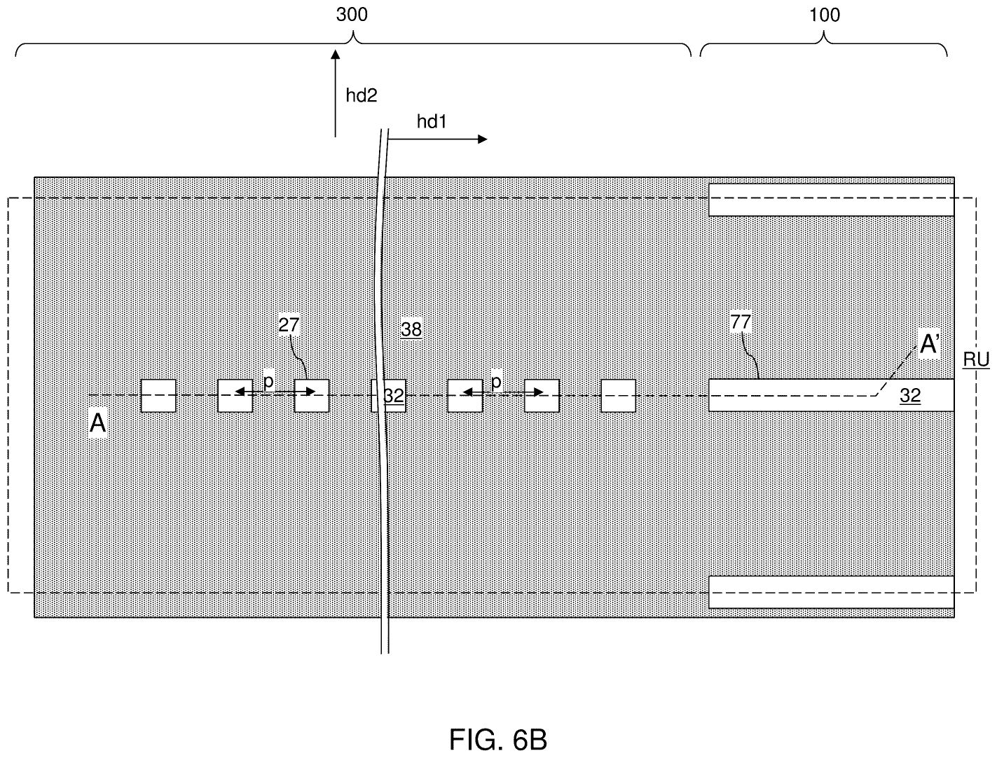

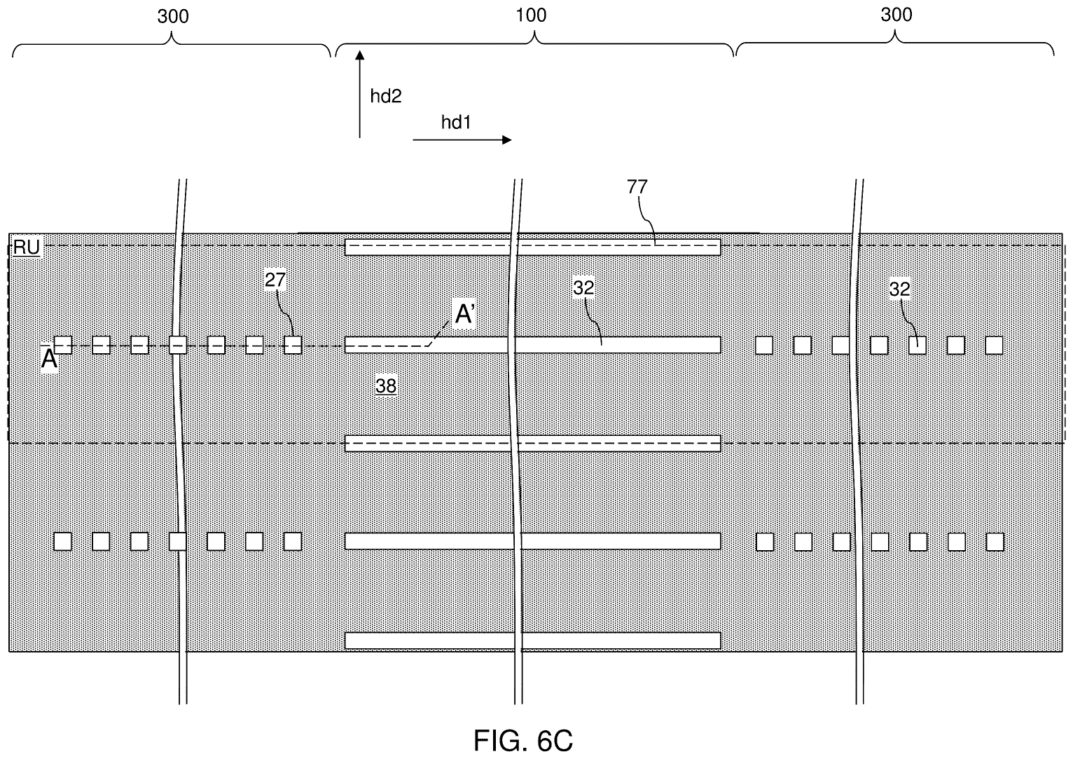

Referring to FIGS. 6A-6C, a patterned hard mask layer 38 can be formed over the topmost insulating layer 32T. The patterned hard mask layer may comprise a semiconductor material, such as amorphous silicon and/or a metallic material, such as TiN. The openings in the patterned hard mask layer 38 may have the pattern of all of the lateral isolation trenches and access via cavities to be subsequently formed. The openings in the patterned hard mask layer 38 include elongated openings 77 laterally extending from one end of the memory array region 100 to another end of the memory array region 100 along the first horizontal direction hd1 such that each end of the elongated openings 77 has an areal overlap with a respective underlying one of the support wall structures 120. Further, the openings in the patterned hard mask layer 38 include rows of discrete openings 27 that are formed in a contact region 300 within a respective one of the repetition unit RU.

In one embodiment, each repetition unit RU may comprise two elongated openings 77 and one row of discrete openings 27 per contact region 300. Thus, in case two contact regions 300 adjoin the memory array region 100, each repetition unit RU may comprise two elongated openings 77 and two rows of discrete openings 27, as shown in FIG. 6C. In one embodiment, each row of discrete openings 27 may be arranged along the first horizontal direction hd1 with a uniform pitch p, as shown in FIGS. 6A and 6B. In one embodiment, the elongated openings 77 may have a uniform width along the second horizontal direction hd2, which may be in a range from 200 nm to 2 microns, although lesser and greater widths may also be employed. Each elongated opening 77 may have a respective horizontal cross-sectional shape of a rectangle or a rounded rectangle. The discrete openings 27 may have a lateral dimension (such as a length or a width) in a range from 200 nm to 2 microns, although lesser and greater lateral dimensions may also be employed. In one embodiment, the discrete openings 27 may have a respective horizontal cross-sectional shape of a circle, an oval, a rectangle, a rounded rectangle, or any other two-dimensional shape having a closed periphery.

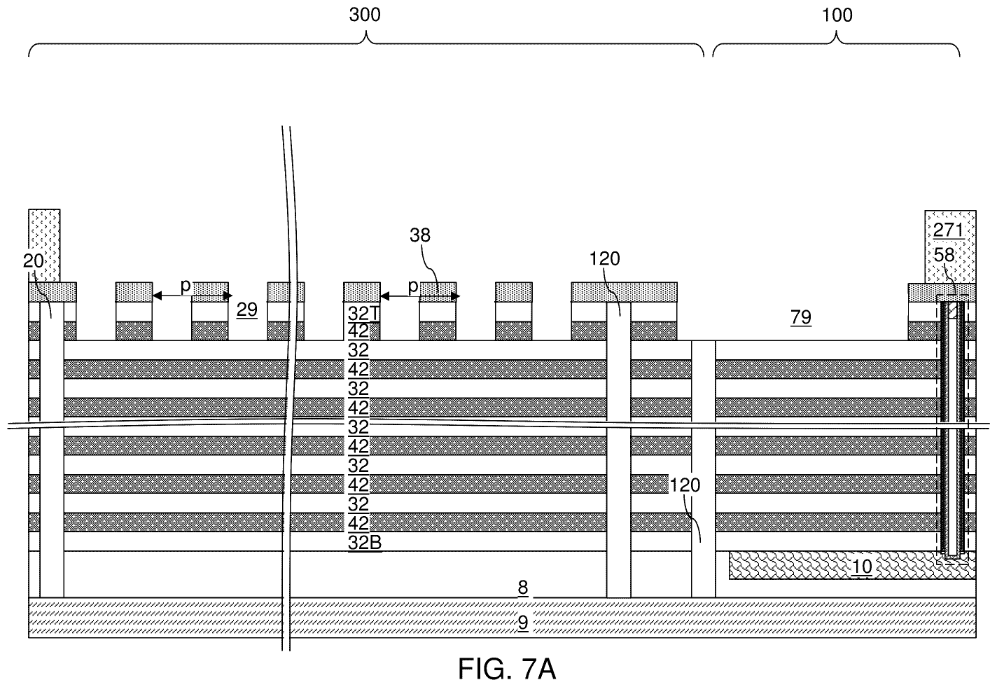

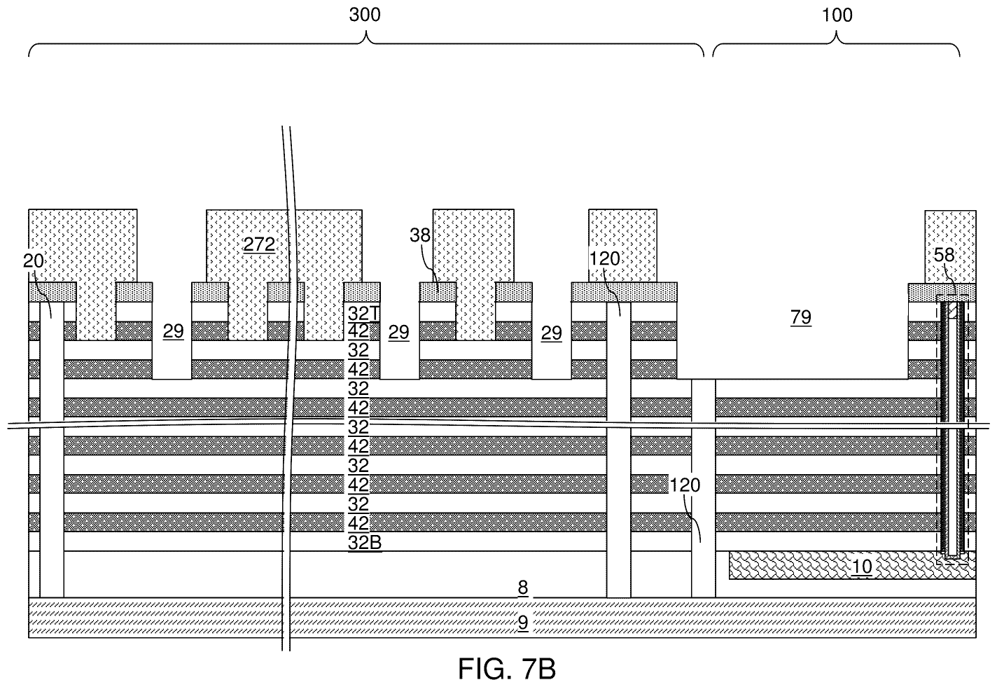

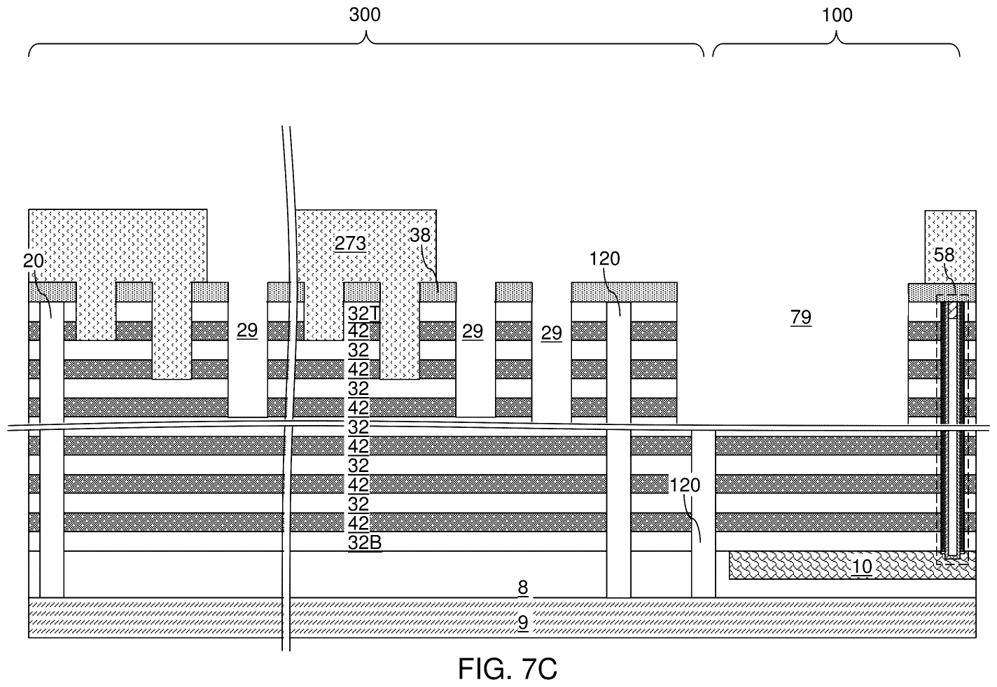

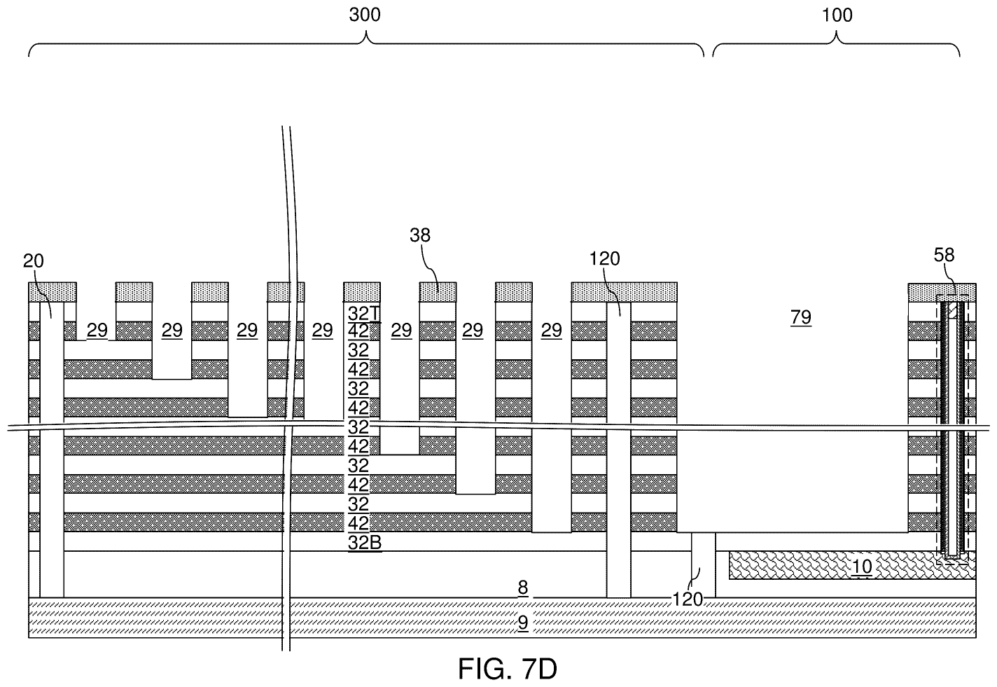

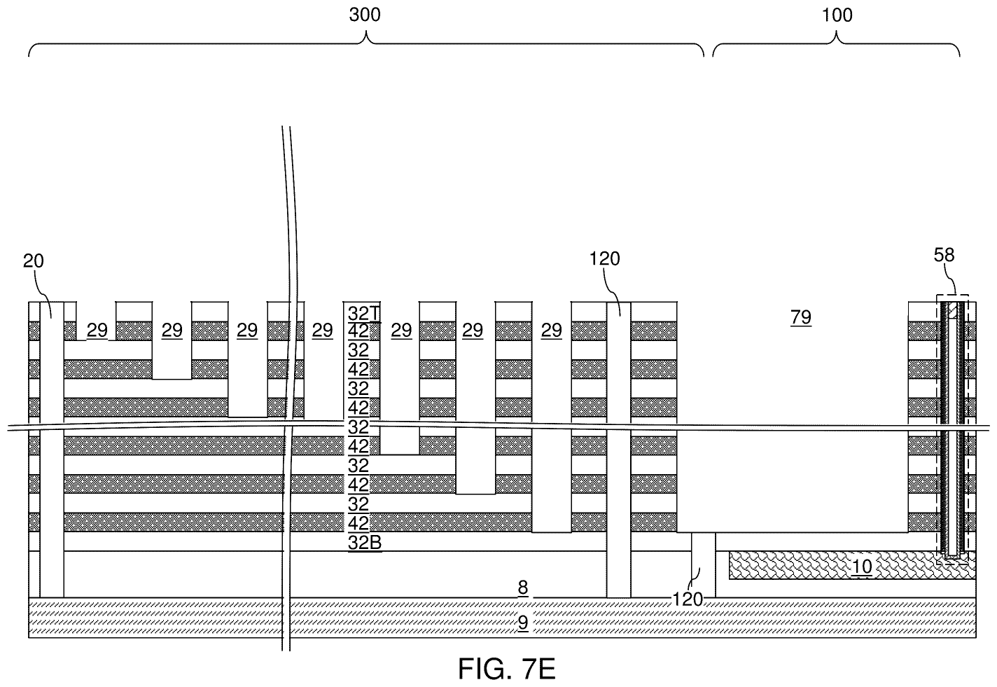

Referring to FIGS. 7A-7D, a set of unit processing steps may be iteratively performed with changes in masking patterns through use of patterned photoresist layers (271, 272, 273). The set of processing steps comprises a patterned photoresist formation step that forms a respective patterned photoresist layer layers (271, 272, 273) that covers a respective subset of the discrete openings 27 without covering the elongated openings 77; and an anisotropic etch step that etches portions of the alternating stack (32, 42) that are not masked by the patterned hard mask layer 38 or the respective patterned photoresist layer (271, 272, 273).

In one embodiment, multiple iterations of a combination of a respective masking process and a respective anisotropic etch process may be performed to etch through a respective subset of sacrificial material layers 42 and a respective subset of the insulating layers 32 underneath each opening (79, 29) in the patterned hard mask layer 38. Each masking process may employ a respective patterned photoresist layers (271, 272, 273, etc.) that masks a respective subset of the openings (79, 29) in the patterned hard mask layer 38 without masking a respective complementary subset of the openings. Each anisotropic etch process etches a respective number of sacrificial material layers 42 and a respective number of insulating layers 32 underneath each opening in the patterned hard mask layer 38 that is not masked by a respective patterned photoresist layer. In one embodiment, etch depths of the anisotropic etch steps are different among the unit processing steps within the set of unit processing steps. The patterned photoresist layers (271, 272, 273, etc.) can be removed after a respective anisotropic etch process, for example, by ashing.

In one embodiment, the number of etched sacrificial material layers 42 and etched insulating layers 32 underneath unmasked openings in the patterned hard mask layer 38 may be a non-negative integer power of 2, i.e., 1, 2, 4, 8, 16, 32, 64, etc. By employing a combination of various masking patterns for the patterned photoresist layers, the total depths of the access via cavities 29 can be varied to enable physical exposure of the top surfaces of sacrificial material layers 42 at each level of the electrically conductive layers 46. The patterned hard mask layer 38 can be subsequently removed. The lateral dimensions (such as diameters) of the access via cavities 29 may be in a range from 30 nm to 300 nm, although lesser and greater lateral dimensions may also be employed. Generally, a access via cavity 29 may vertically extend through an alternating stack of insulating layers 32 and sacrificial material layers 42.

According to an aspect of the present disclosure, the patterns of the patterned photoresist layers (271, 272, 273, etc.) are selected such that the areas of the elongated openings 77 in the patterned hard mask layer 38 are not masked by any of the patterned photoresist layers (271, 272, 273, etc.). A lateral isolation trench 79 can be formed underneath each elongated opening 77 in the patterned hard mask layer 38. Generally, the patterns of the patterned photoresist layers (271, 272, 273, etc.) are selected such that access via cavities 29 underneath each row of discrete openings 27 in the patterned hard mask layer 38 are formed with different depths. Further, the depths of the access via cavities 29 within each row of access via cavities 29 decreases with a lateral distance from a most proximal boundary between a contact region 300 and the memory array region 100. In addition, patterns of the patterned photoresist layers (271, 272, 273, etc.) may be selected such that each of the sacrificial material layers 42 can be physically exposed to a respective access via cavity 29 within each row of access via cavities 29 located within a respective repetition unit RU and within a respective contact region 300. In one embodiment, all insulating layers 32 other than the topmost insulating layer 32T may have a respective top surface that is physically exposed to a respective access via cavity 29 for each row of access via cavities 29 located within a respective repetition unit RU and within a respective contact region 300. Each of the sacrificial material layers 42 can be physically exposed to each lateral isolation trenches 79. In one embodiment, each of the lateral isolation trenches 79 may vertically extend through each sacrificial material layer 42. The lateral isolation trenches 79 may, or may not, vertically extend to a top surface of the source layer 10.

Referring to FIG. 7E, the patterned hard mask layer 38 may be removed, for example, by performing an isotropic etch process that removes the material of the patterned hard mask layer 38 selective to materials of the insulating layers 32 and the sacrificial material layers 42. For example, if the patterned hard mask layer 38 comprises a semiconductor material, a wet etch process that etches the semiconductor material selective to the materials of the insulating layers 32 and the sacrificial material layers 42 may be performed.

Generally, the lateral isolation trenches 79 and the access via cavities 29 can be formed in the alternating stack (32, 42). Each of the sacrificial material layers 42 is exposed to each of the lateral isolation trenches 79. The access via cavities 29 within each row of access via cavities 29 may have different depths, and may be arranged along the first horizontal direction hd1 within a uniform pitch p. Each of the sacrificial material layers 42 can be physically exposed to a respective access via cavity 29 within each row of access via cavities 29, and the depths of the access via cavities 29 can decrease with a lateral distance from a most proximal boundary between the memory array region 100 and the contact region 300 in which the row of access via cavities 29 is located.

According to an aspect of the present disclosure, the pattern of the lateral isolation trenches 79 can be selected such that each patterned portion of the sacrificial material layers 42 can continuously extend into one of the contact regions 300 through a gap between a respective neighboring pair of support wall structures 120 that are laterally spaced apart along the second horizontal direction hd2. In one embodiment, each of the support wall structures 120 can be located between a respective one of the lateral isolation trenches 79 and a respective row of access via cavities 29. In one embodiment, each of the support wall structures 120 may comprise a section that is perpendicular to a lengthwise direction (i.e., the first horizontal direction hd1) of the lateral isolation trenches 79.

In one embodiment, for each support wall structure 120, the lateral isolation trenches 79 and a respective row of access via cavities 29 can be formed on opposite sides of the support wall structure 120. In one embodiment, each of the support wall structures 120 may be intersected by a respective pair of adjacent lateral isolation trenches 79. Each of the support wall structures 120 can be physically exposed to a respective subset of the lateral isolation trenches 79, such as a pair of lateral isolation trenches 79. In one embodiment, at least one of the lateral isolation trenches 79 may cut a respective one of the support wall structures 120. In one embodiment, at least one of the support wall structures 120 may be cut by a respective pair of lateral isolation trenches 79, and may be divided into a pair of dielectric material portions, i.e., support wall segments.

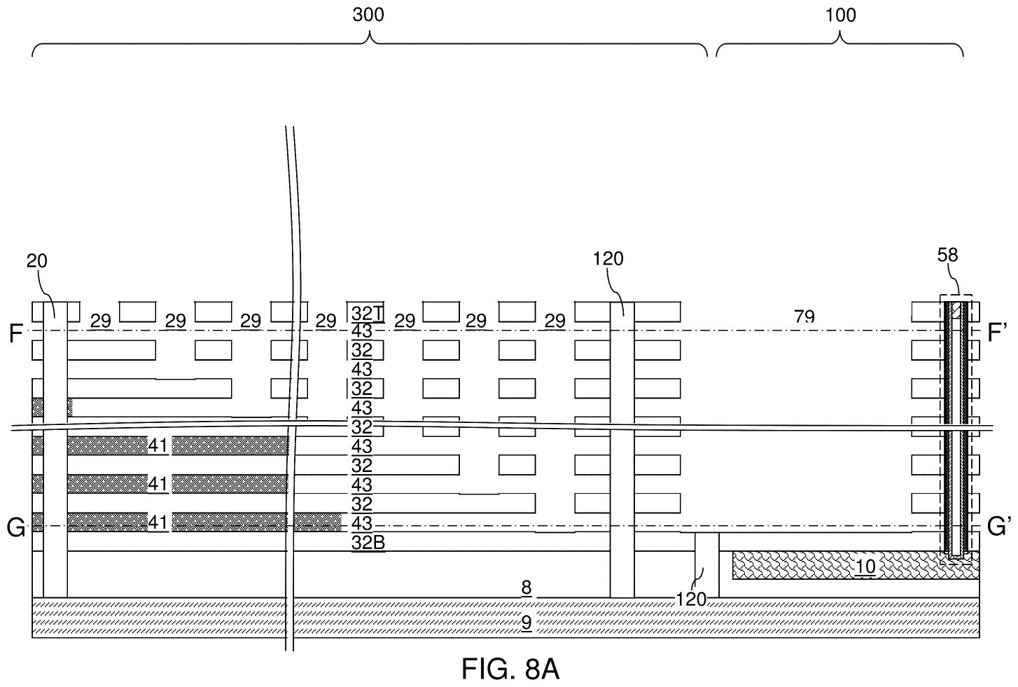

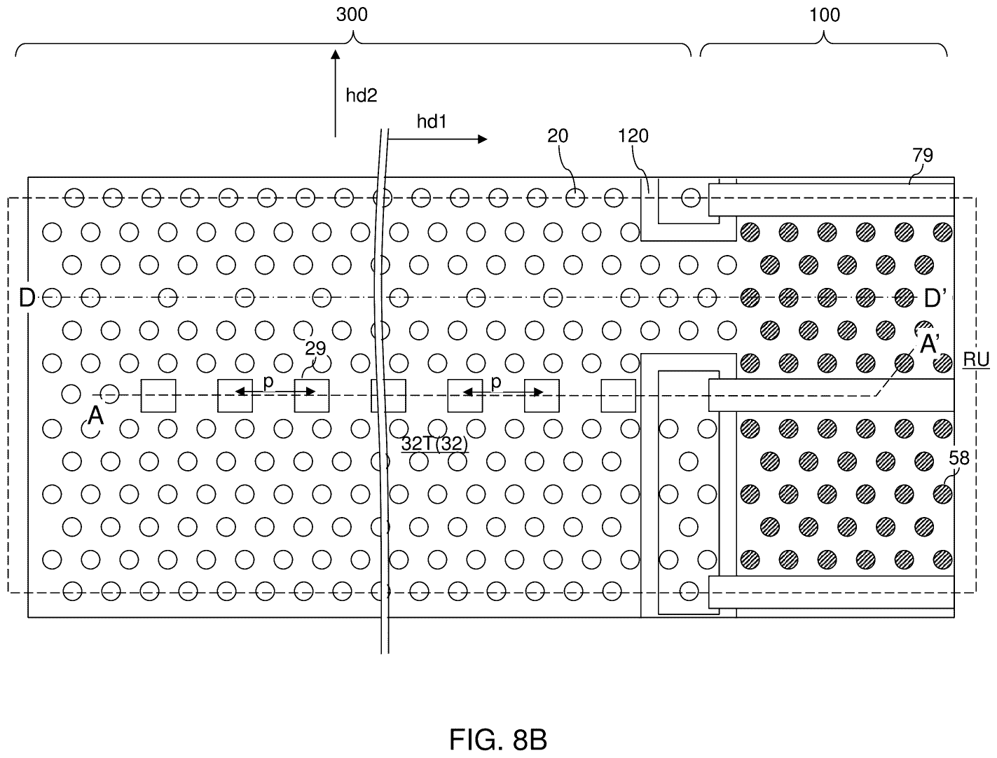

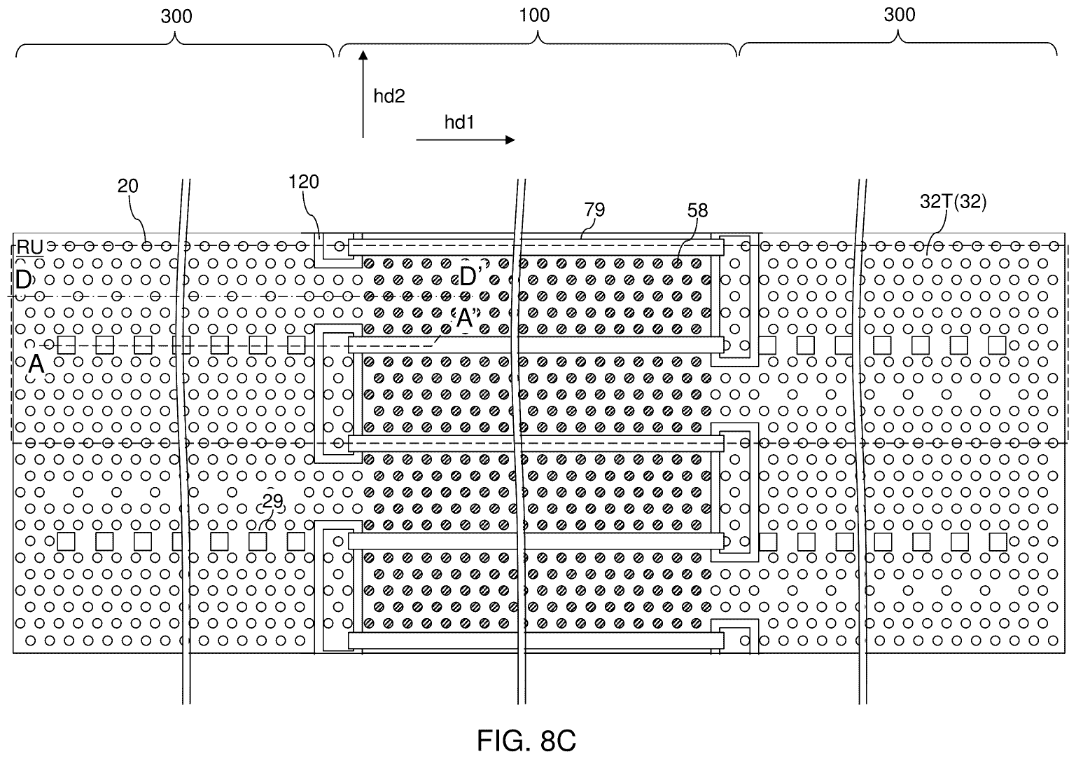

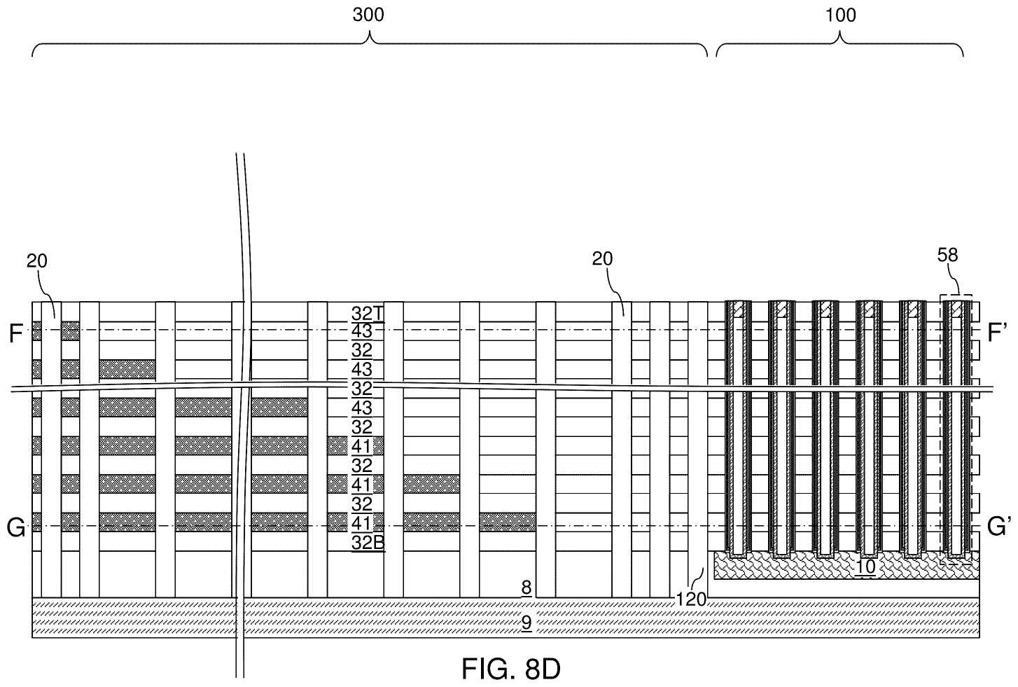

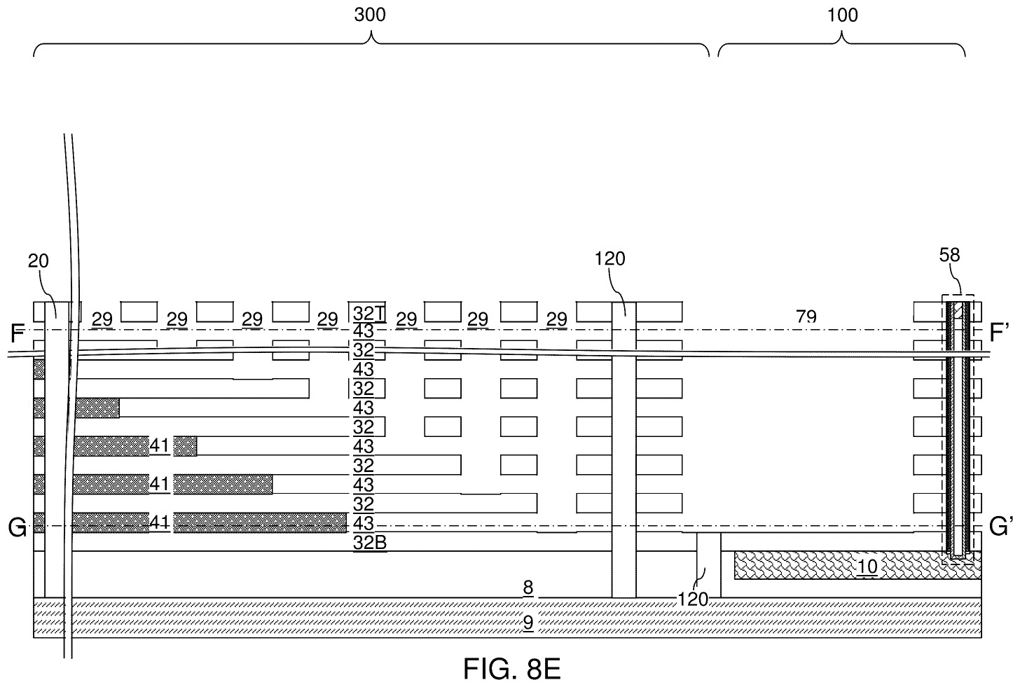

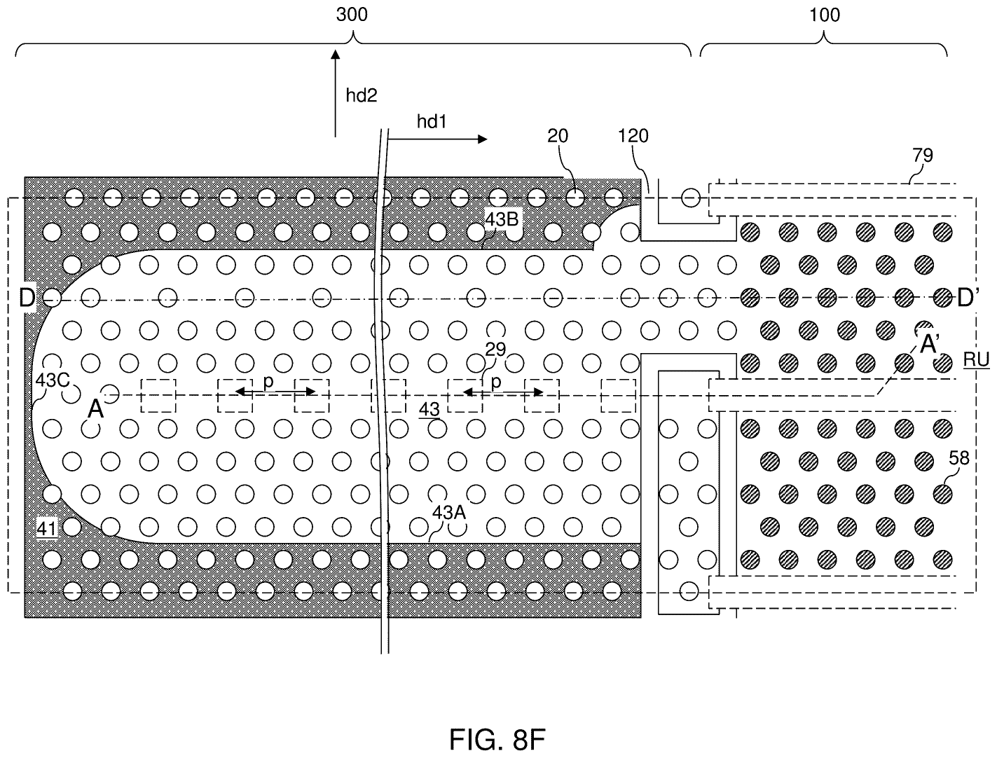

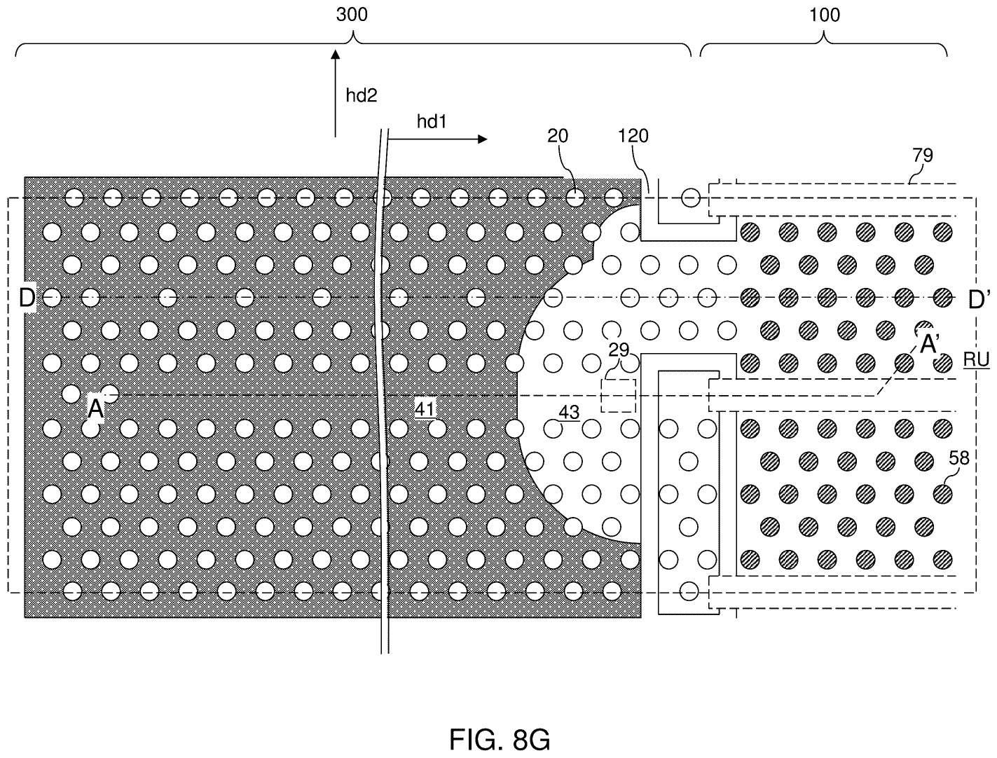

Referring to FIGS. 8A-8G, an isotropic etch process can be performed to etch the material of the sacrificial material layers 42 selective to materials of the insulating layers 32 by providing the etching medium into the lateral isolation trenches 79 and the access via cavities 29. For example, if the sacrificial material layers 42 comprise silicon nitride, a wet etch process employing hot phosphoric acid may be performed to remove portions of the sacrificial material layers 42 that are proximal to the lateral isolation trenches 79 and access via cavities 29 by providing phosphoric acid into the lateral isolation trenches 79 and the access via cavities 29. Each lateral recess 43 can be formed within a respective volume from which a portion of a respective sacrificial material layers 42 is etched. The duration of the isotropic etch process can be selected such that the lateral etch distance of the isotropic etch process is greater than one half of the lateral spacing between a neighboring pair of lateral isolation trenches 79. In this case, the sacrificial material layers 42 can be entirely removed from the memory array region 100. Further, the duration of the isotropic etch process can be selected such that each of the sacrificial material layers 42 comprises a remaining portion in each contact region 300 after the isotropic etch process. Each remaining portion of a sacrificial material layer 42 is herein referred to as a dielectric material layer 41. The dielectric material layers 41 can be formed at each level at which the sacrificial material layers 42 are provided.

Generally, the lateral recesses 43 can be performed by isotropically recessing the sacrificial material layers 42 around the lateral isolation trenches 79 and the access via cavities 29. The lateral extents of the lateral recesses 43 can be different for different levels, i.e., as a function of the depth of the access via cavities 29 relative to the substrate 9. As discussed above, the depth of the access via cavities 29 may decrease with a lateral distance from a most proximal boundary between the memory array region 100 and a contact region 300 (i.e., the farther from the boundary, the shallower the access via cavity 29 depth, as shown in FIGS. 8A and 8E). In one embodiment, the depth of the access via cavities 29 may decrease with a lateral distance from a most proximal support wall structure 120. In this case, for each pair of lateral recesses 43 located in a respective contact region 300, the overlying lateral recess 43 has a greater lateral extent than the underlying lateral recess 43. In one embodiment, the lateral extents of the lateral recesses 43 increase with a vertical distance the top surface of the substrate 9. In one embodiment, lateral extents of the dielectric material layers 41 decreases with the vertical distance from the top of the substrate 9.

According to an aspect of the present disclosure, the isotropic etch process etches the material of the sacrificial material layers 42 isotropically, i.e., at an etch rate that is independent of the etch direction. As a consequence, each of the dielectric material layers 41 may comprise a sidewall segment that is equidistant from a periphery of a most proximal one of the access via cavities 29. In one embodiment, a vertically neighboring pair of boundaries between a respective lateral recess 43 and a respective dielectric material layer 41 within the same horizontal plane in the contact region 300 may be laterally offset from each other by the uniform pitch p. In one embodiment shown in FIG. 8F, a subset of the boundaries between a respective lateral recess 43 and a respective dielectric material layer 41 may comprise a respective pair of lengthwise boundary segments (43A, 43B) that laterally extend along the first horizontal direction hd1 and are separated along the second horizontal direction hd2, and a respective pair of vertically-straight and horizontally-concave surface segments 43C. Each lateral recess 43 may continuously extend through the entire length of the memory array region 100 along the first horizontal direction hd1, may laterally extend through a gap 120G between a respective pair of support wall structures 120, and may laterally extend through a respective portion of a contact region 300 along the first horizontal direction hd1 such that the lateral extent of the respective portion of the lateral recess 43 is less than the total lateral extent of the contact region 300 along the first horizontal direction hd1. In one embodiment, each of the lateral recesses 43 may laterally surround at least one access via cavity 29 within a respective row of access via cavities 29. Each lateral recess 43 laterally surrounds a respective two-dimensional array of memory opening fill structures 58 and a respective subset of the support pillar structures 20.

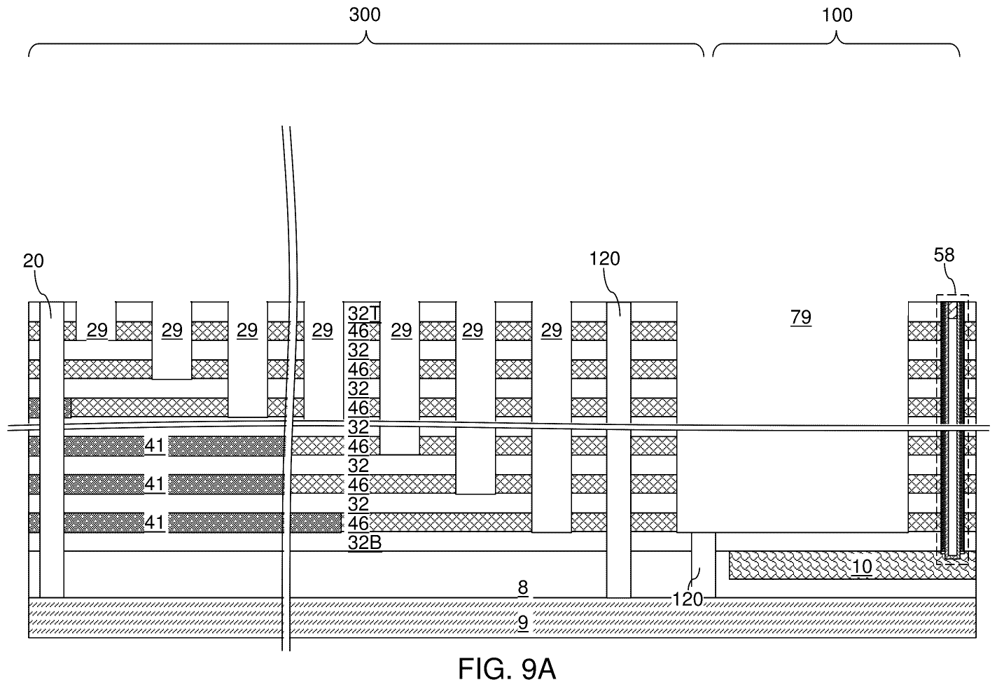

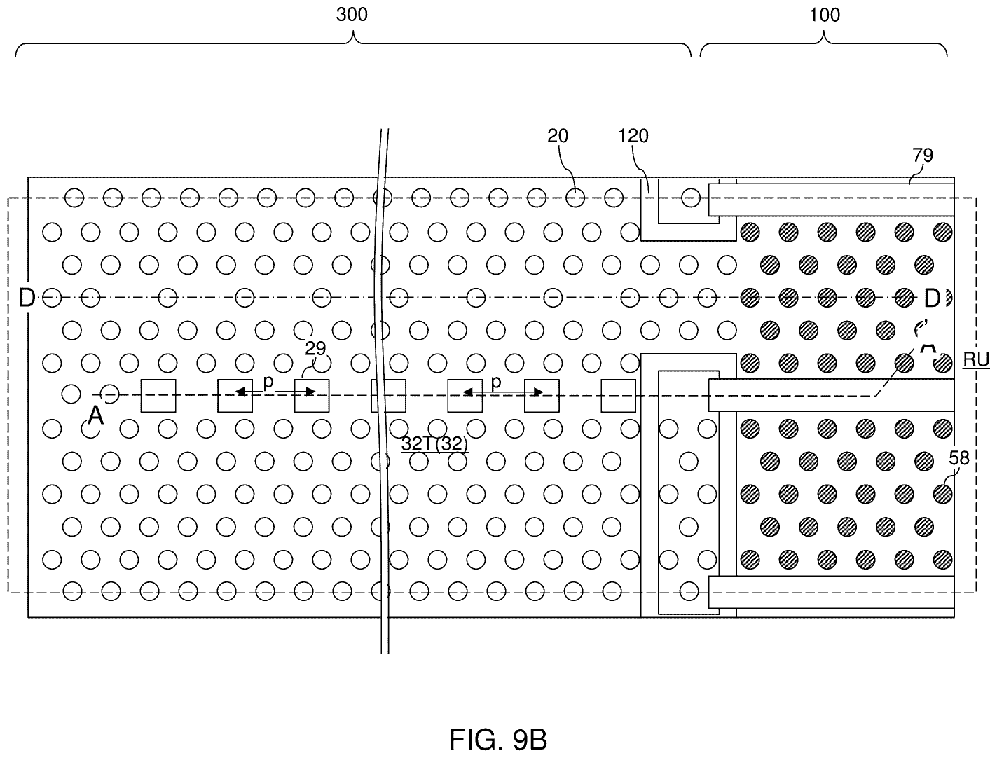

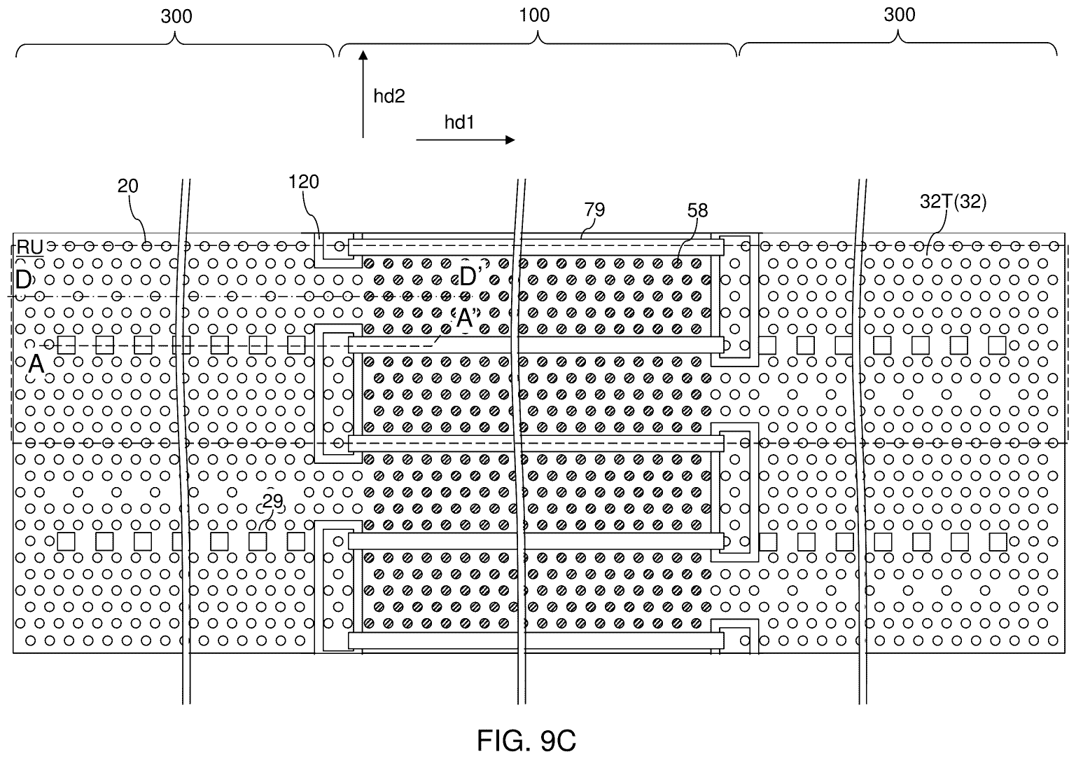

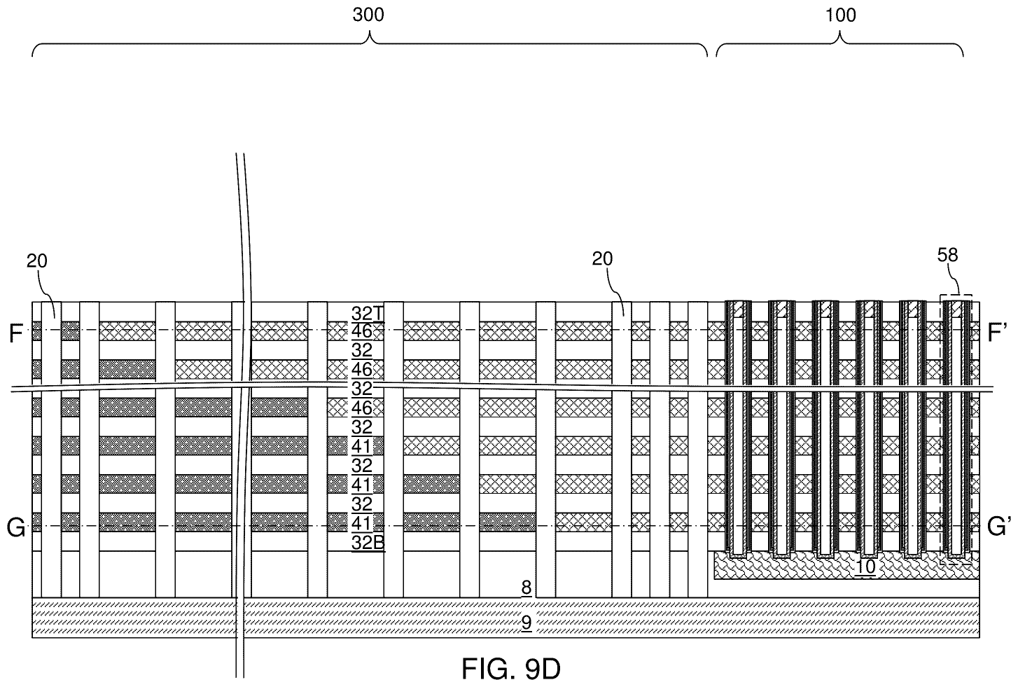

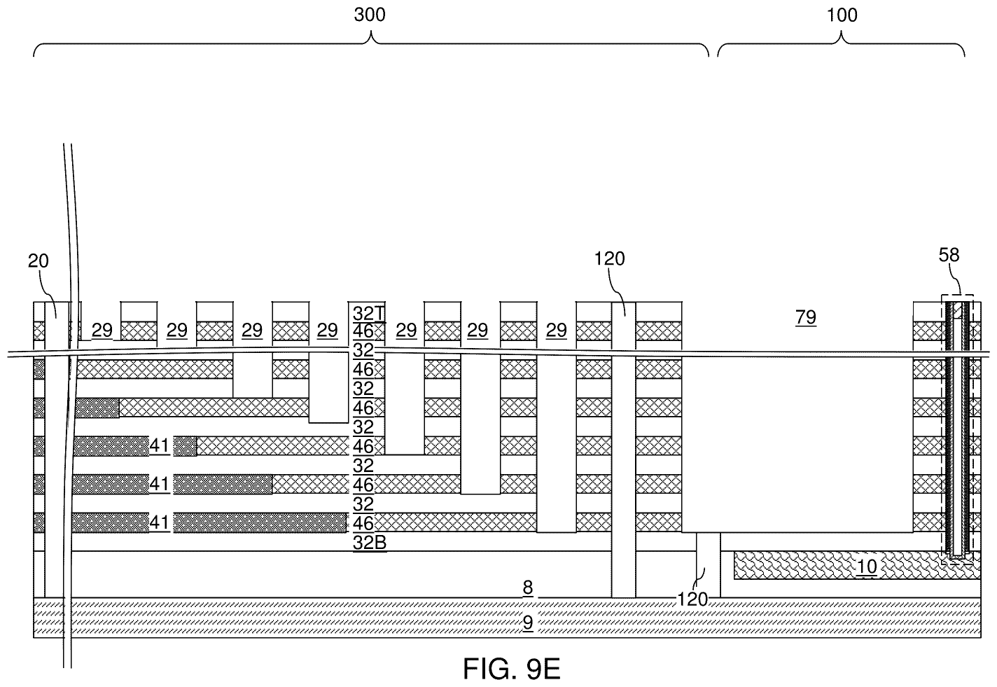

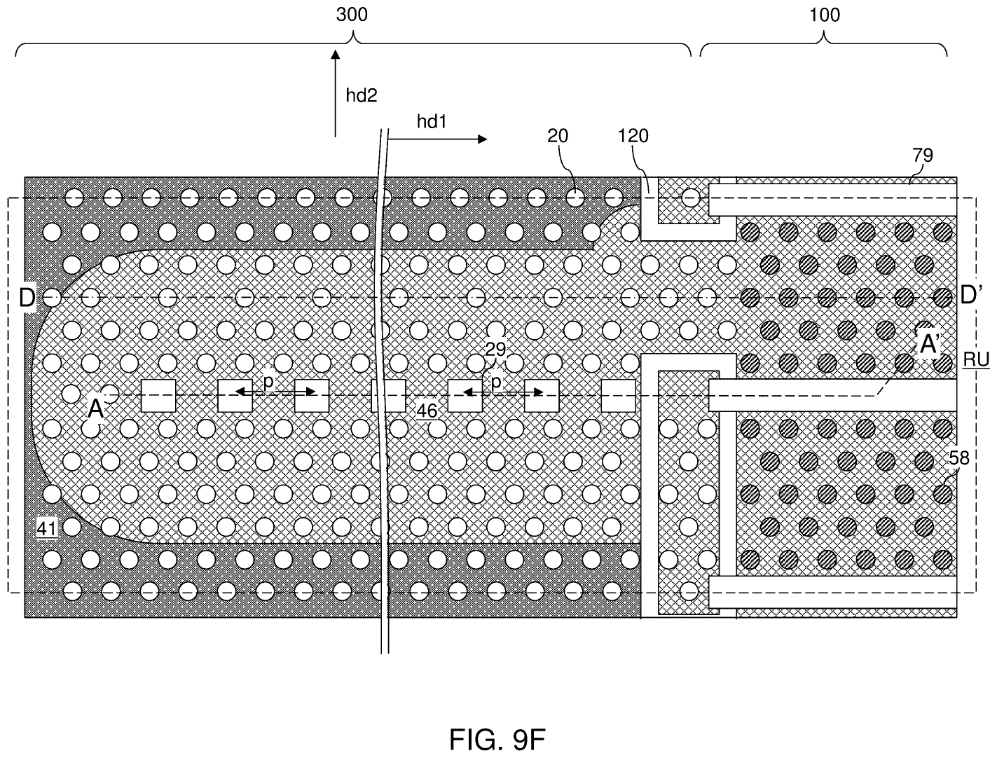

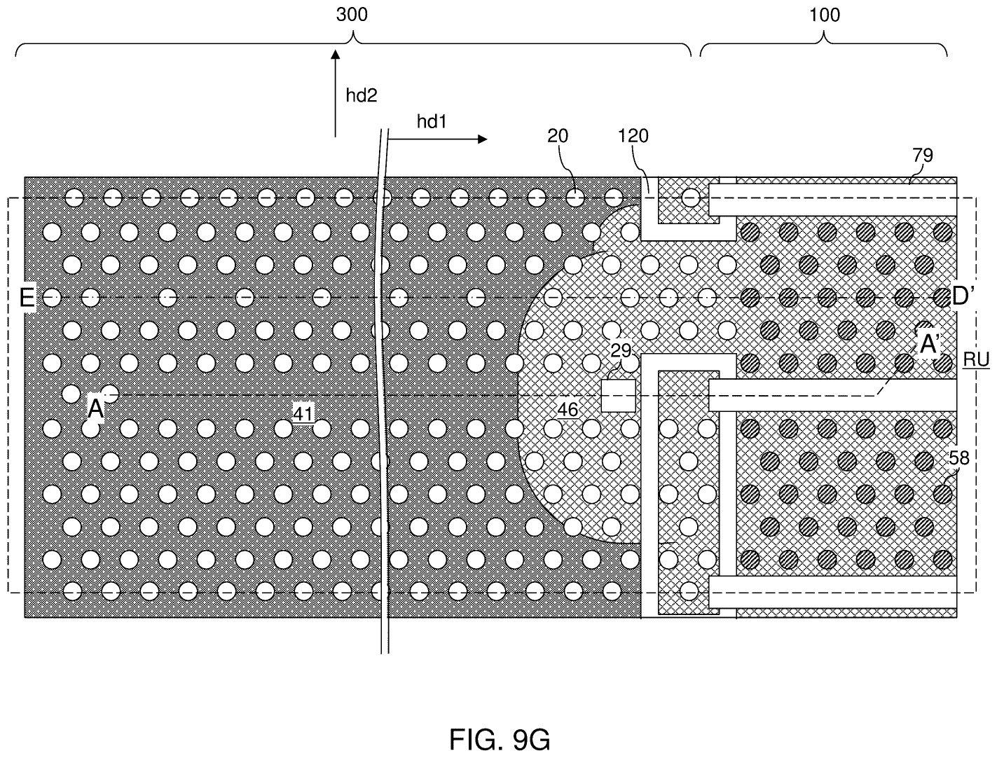

Referring to FIGS. 9A-9G, a backside blocking dielectric layer (not shown) can be optionally formed in the lateral recesses 43 by a conformal deposition process. At least one conductive material, such as at least one metallic material, can be conformally deposited in the lateral recesses 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. The at least one conductive metallic material can be deposited in the lateral recesses 43 and at peripheral portions of the lateral isolation trenches 79 and the access via cavities 29 by performing at least one conformal deposition process such as at least one atomic layer deposition and/or at least one chemical vapor deposition. The lateral isolation trenches 79 and the access via cavities 29 can be employed as conduits for transporting precursor materials for deposition of the at least one conductive material. The duration of the at least one conformal deposition process can be selected such that the lateral recesses 43 are filled with the at least one conductive material, while each of the lateral isolation trenches 79 and the access via cavities 29 comprises a respective central void that is not filled with the at least one conductive material.

Excess portions of the at least one conductive material that are deposited in the lateral isolation trenches 79 and the access via cavities 29 or above the topmost insulating layer 32T can be removed by performing an etch-back process, which may comprise an isotropic etch process and/or an anisotropic etch process. Each remaining portion an electrically conductive layer 46 and at least one dielectric material layer 41 that is in direct contact with the electrically conductive layer 46 or is laterally spaced from the electrically conductive layer 46 only by a vertically-extending portion of a backside blocking dielectric layer (not shown) constitutes a composite layer (41, 46).

An alternating stack {32, (46, 41)} of insulating layers 32 and composite layers (46, 41) can be formed over the source layer 10 and over the substrate 9. Each of the composite layers (46, 41) includes at least a combination of a respective dielectric material layer 41 and a respective electrically conductive layer 46. Lateral extends of the electrically conductive layers 46 in the alternating stack {32, (46, 41)} increase with a vertical distance from the top surface of the substrate 9 (e.g., increase from a horizontal plane including an interface between the source layer 10 and the alternating stack {32, (46, 41)}).

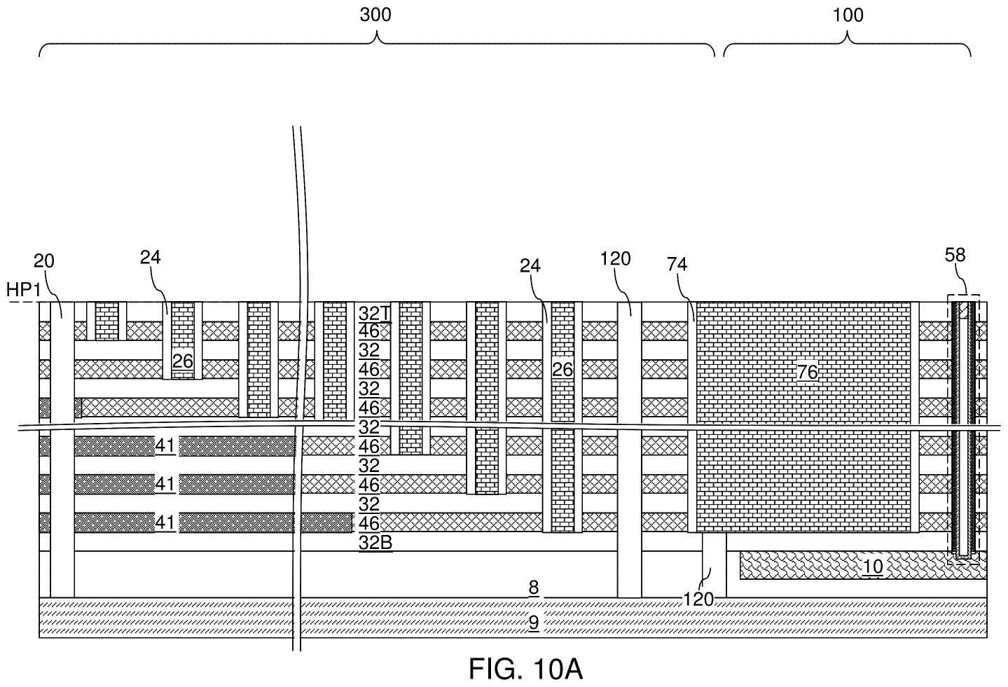

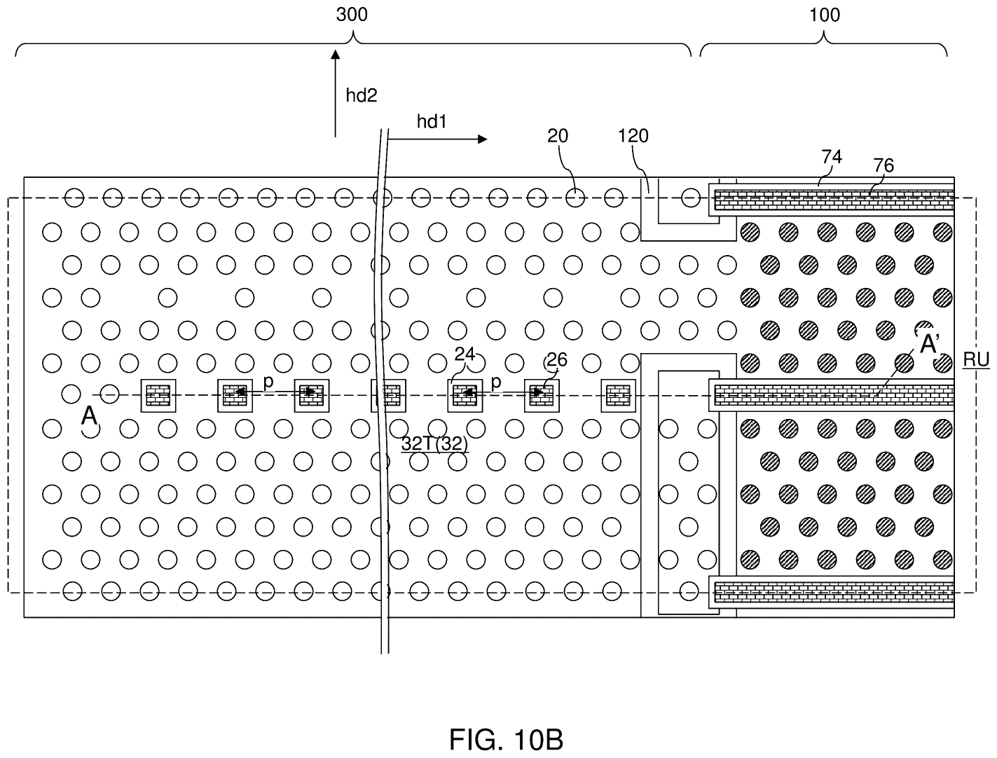

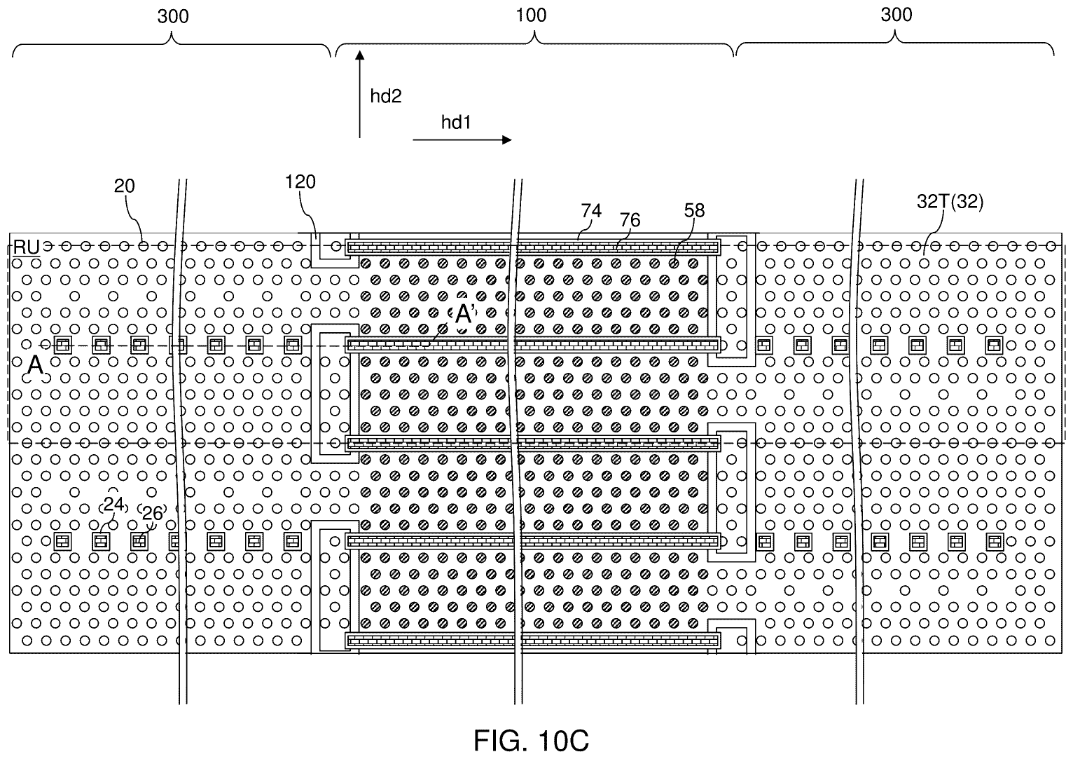

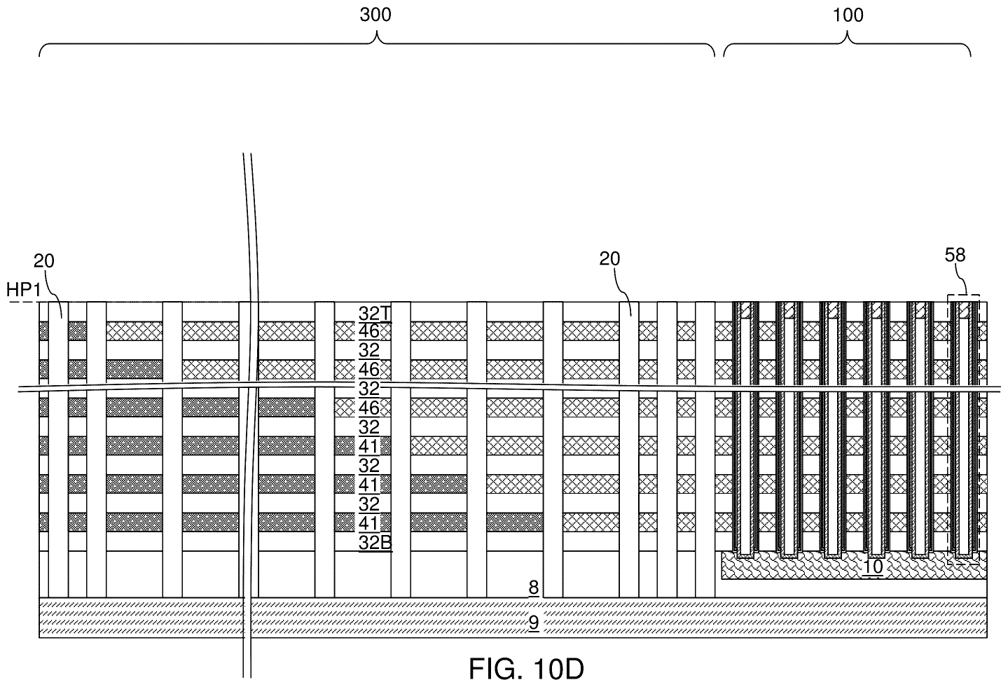

Referring to FIGS. 10A-10D, at least one fill material can be deposited in the lateral isolation trenches 79 and the access via cavities 29. Via-fill pillar structures (24, 26) may be formed in each of the access via cavities 29, and lateral isolation trench fill structures (74, 76) may be formed in each of the lateral isolation trenches 79. Generally, the via-fill pillar structures (24, 26) and the lateral isolation trench fill structures (74, 76) comprise dielectric surfaces that contact a respective subset of layers with a respective alternating stack {32, (46, 41)} of insulating layers 32 and composite layers (46, 41).

In an illustrative example, an insulating fill material such as undoped silicate glass or a doped silicate glass can be conformally deposited in the lateral isolation trenches 79 and the access via cavities 29 by a conformal deposition process. An anisotropic etch process may be optionally performed. A conductive fill material and/or a heavily doped semiconducting fill material may be deposited in remaining volumes of the lateral isolation trenches 79 and the access via cavities 29. Portions of the conductive fill material and/or the semiconducting fill material overlying the horizontal plane including the top surface of the topmost insulating layer 32T, and any remaining portion of the insulating fill material overlying the horizontal plane including the top surface of the topmost insulating layer 32T (if present), can be removed by performing a planarization process. The planarization process may comprise a recess etch process and/or a chemical mechanical polishing (CMP) process. Each remaining portion of the insulating fill material, the conductive fill material, and/or the semiconducting fill material filling an access via cavity 29 constitutes a via-fill pillar structure (24, 26). Each remaining portion of the insulating fill material, the conductive fill material, and/or the semiconducting fill material filling a lateral isolation trench 79 constitutes an lateral isolation trench fill structures (74, 76), Each via-fill pillar structure (24, 26) comprises an insulating via-fill material portion 24 including a remaining portion of the insulating fill material, and an optional inner via fill material portion 26 which comprises a remaining portion of the conductive fill material or the heavily doped semiconducting fill material. Each lateral isolation trench fill structures (74, 76) comprises an insulating trench-fill material portion 74 including a remaining portion of the insulating fill material, and may optionally include an inner trench fill material portion 76 which comprises a remaining portion of the conductive fill material or the heavily doped semiconducting fill material.

Generally, the lateral isolation trench fill structures (74, 76) and the via-fill pillar structures (24, 26) can be formed in the lateral isolation trenches 79 and the access via cavities 29, respectively. Each of the via-fill pillar structures (24, 26) vertically extends through and contacts a respective subset of the electrically conductive layers 46, and have top surfaces within a first horizontal plane HP1 that may include the top surface of the topmost insulating layer 32T, and have bottom surfaces at different vertical distances from the first horizontal plane HP1.

The lateral isolation trench fill structures (74, 76) are located in a respective one of the lateral isolation trenches 79. The lateral isolation trenches 79 vertically extend through each of the composite layers (46, 41) within the alternating stack {32, (46, 41)} and laterally extend along the first horizontal direction hd1. In one embodiment, each of the lateral isolation trench fill structures (74, 76) and the via-fill pillar structures (24, 26) comprises a same set of at least one fill material that includes an insulating fill material.

In one embodiment, the support wall structures 120 can be in contact with a respective subset of the lateral isolation trench fill structures (74, 76), and can be in contact with interfaces between a respective insulating layer 32 and a respective electrically conductive layer 46 in the composite layers (46, 41). The support wall structures 120 may vertically extend through each layer within the alternating stack {32, (46, 41)}.

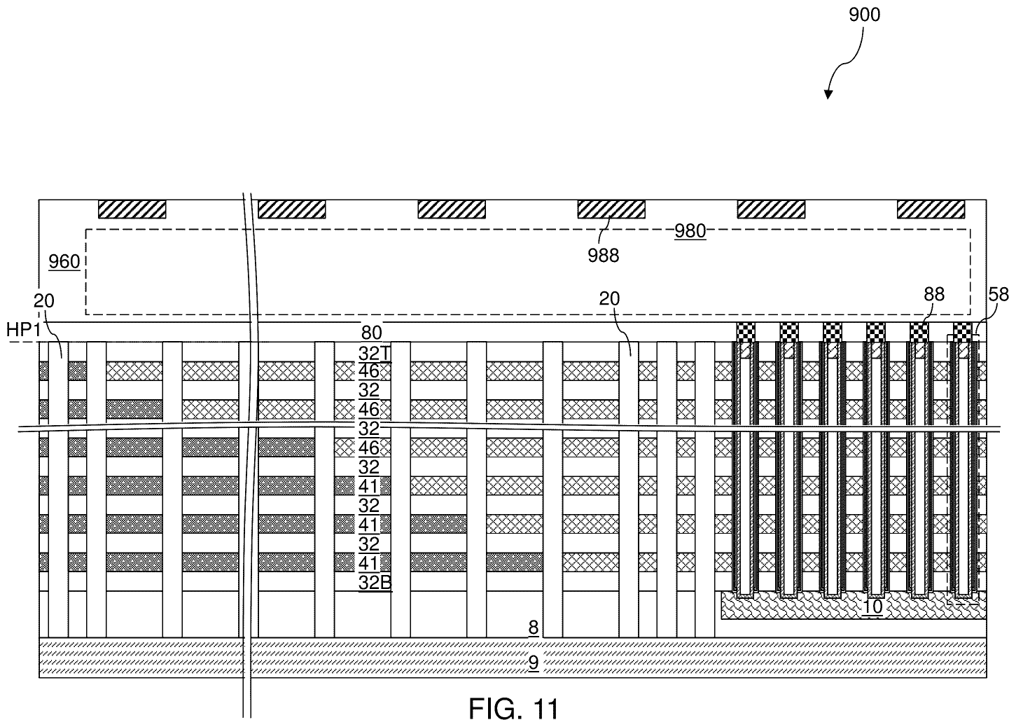

Referring to FIG. 11, a contact-level dielectric layer 80 can be formed over the alternating stacks {32, (46, 41)} by depositing a dielectric material such as silicon oxide. The thickness of the contact-level dielectric layer 80 may be in a range from 100 nm to 600 nm, although lesser and greater thicknesses may also be employed.

A photoresist layer (not shown) can be applied over the contact-level dielectric layer 80, and can be lithographically patterned to form openings therethrough. An anisotropic etch process can be performed to transfer the pattern of the openings in the photoresist layer through the contact-level dielectric layer 80 down to a top surface of a respective one of the drain regions 63. Drain contact via cavities can be formed through the contact-level dielectric layer 80. The photoresist layer can be subsequently removed, for example, by ashing.

At least one conductive material, such as a combination of a metallic barrier material and a metallic fill material, can be deposited in the drain contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88.

Memory-side dielectric material layers 960 and memory-side metal interconnect structures 980 can be formed over the contact-level dielectric layer 80. Memory-side dielectric material layers 960 may include at least one via-level dielectric layer, at least one additional line-level dielectric layer, and/or at least one additional line-and-via-level dielectric layer. The memory-side metal interconnect structures 980 may comprise metal via structures, metal line structures, and/or integrated metal line-and-via structures. The metal line structures may comprise bit lines 108 which electrically contact the drain contact via structures (i.e., the drain electrodes) 88 via one or more metal via structures (not shown for clarity). Metal bonding pads, which are herein referred to as memory-side bonding pads 988, may be formed at the topmost level of the additional dielectric material layers 960. The memory-side bonding pads 988 may be electrically connected to the memory-side metal interconnect structures 980 and various nodes of the three-dimensional memory array including the alternating stacks {32, (46, 41)} of insulating layers 32 and composite layers (46, 41) and the memory opening fill structures 58. Generally, the memory-side dielectric material layers 960 overlie the alternating stacks {32, (46, 41)}, and the memory-side metal interconnect structures 980 and the memory-side bonding pads 988 are embedded in the memory-side dielectric material layers 960. The above steps form a memory die 900.

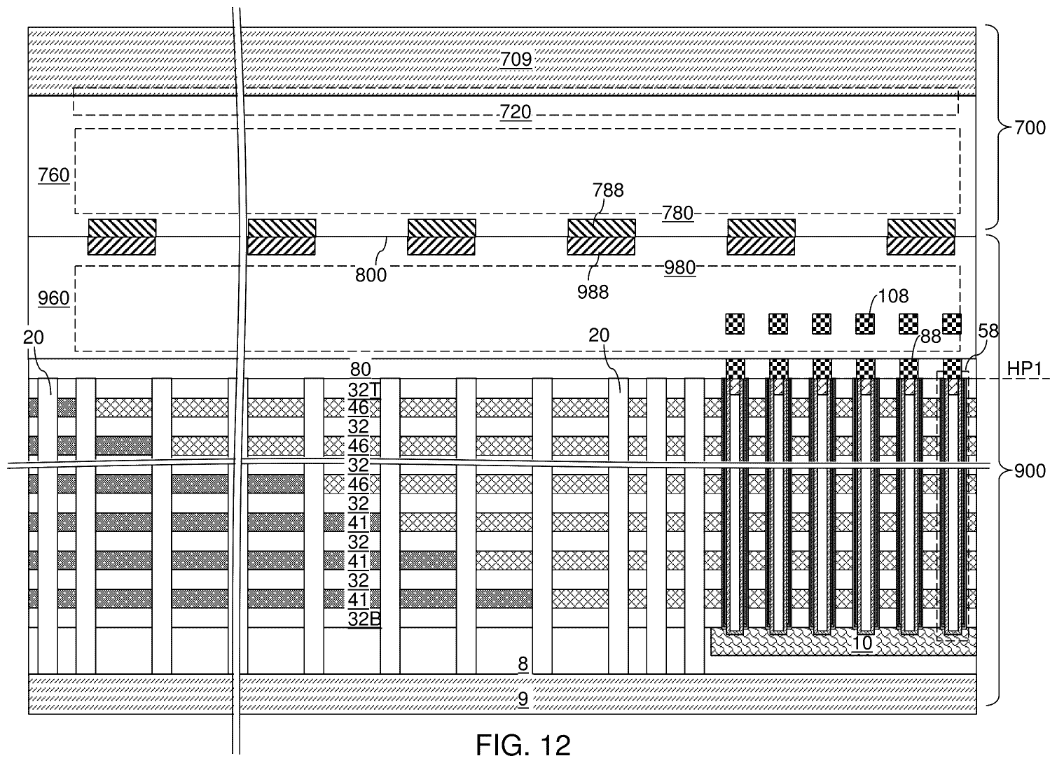

Referring to FIG. 12, a logic die 700 is provided. The logic die 700 includes a logic-side substrate 709, semiconductor devices 720 located on the logic-side substrate 709 and comprising logic-side semiconductor devices (such as field effect transistors), logic-side metal interconnect structures 780 embedded within logic-side dielectric material layers 760, and logic-side bonding pads 778. The semiconductor devices 720 may include a peripheral circuit configured to control operation of the memory array within the memory die 900. In one embodiment, the peripheral circuit may be configured to drive various electrical components within the memory array including, but not limited to, the bit lines 108 (i.e., the peripheral circuit may comprise a bit line driver circuit). In one embodiment, the peripheral circuit may be configured to control operation of the vertical stack of memory elements in the memory array in the memory die 900.

The logic die 700 can be attached to the memory die 900, for example, by bonding the logic-side bonding pads 778 to the memory-side bonding pads 988 at a bonding interface 800. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

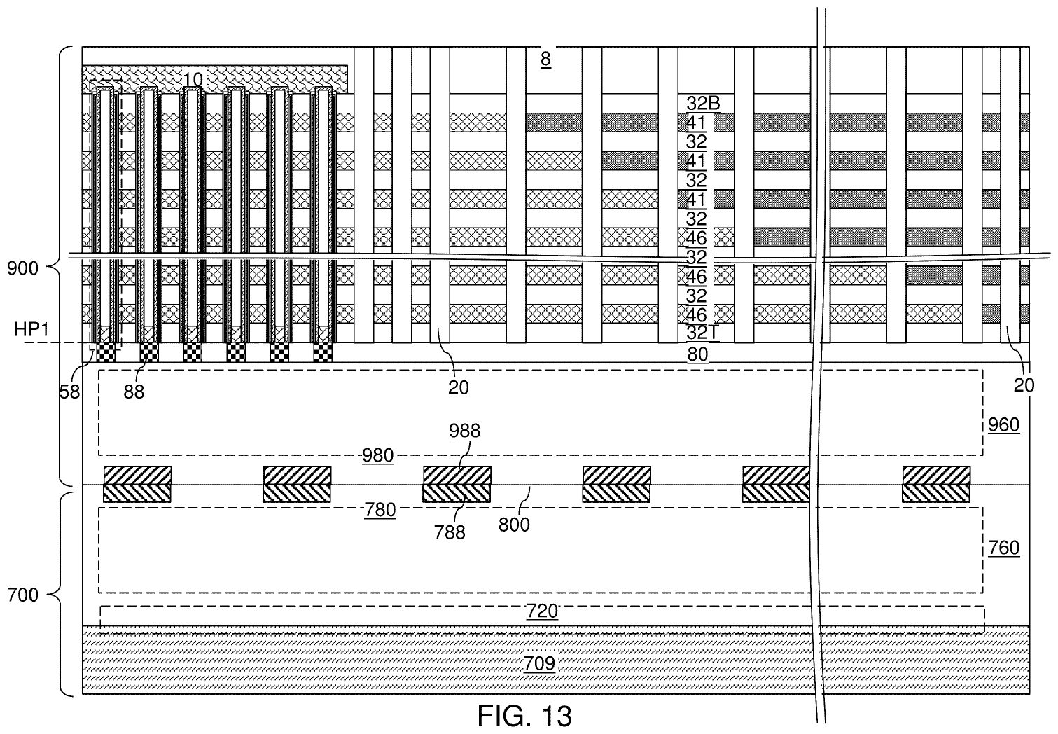

Referring to FIG. 13, the carrier substrate 9 can be removed, for example, by grinding, polishing, cleaving, an isotropic etch process, and/or an anisotropic etch process. The distal of the source-level insulating layer 8 can be physically exposed. As used herein, a distal side of an element in a bonded assembly refers to a side that is distal from a horizontal plane including a bonding interface 800 of the bonded assembly.

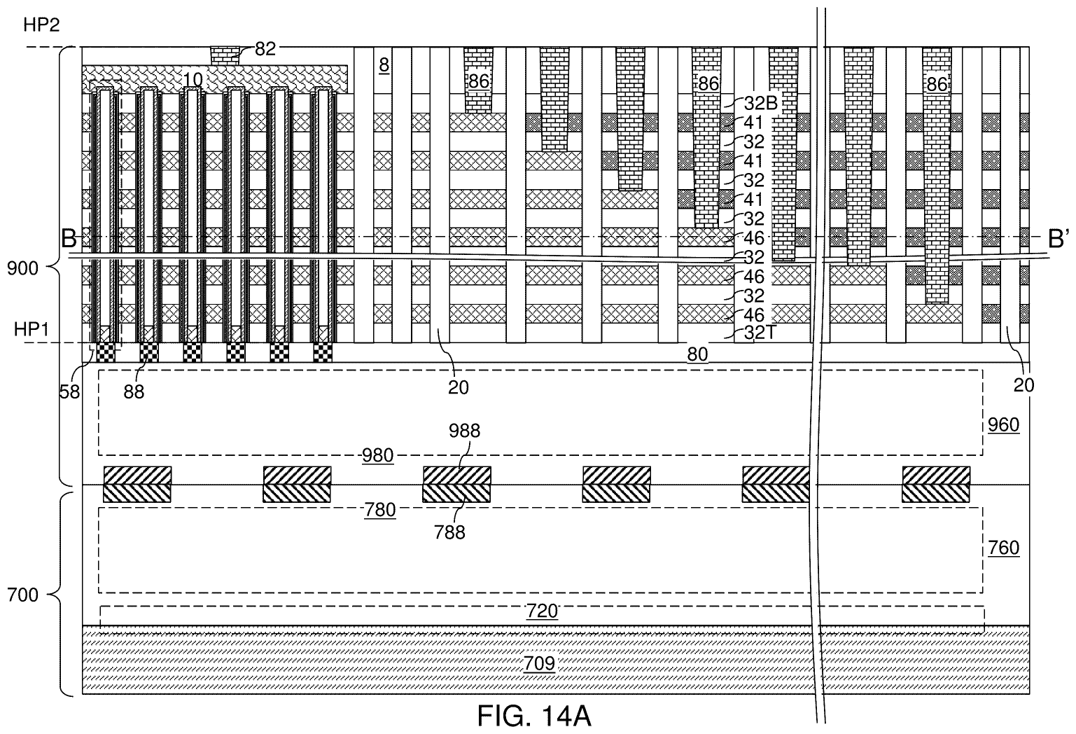

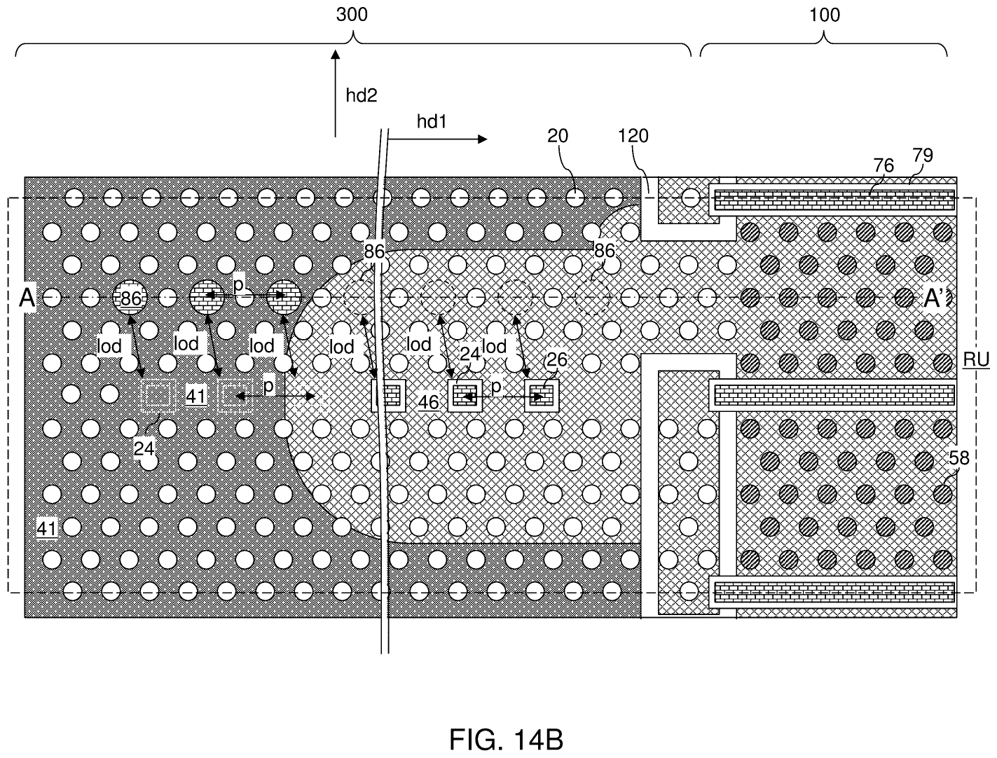

Referring to FIGS. 14A and 14B, a photoresist layer (not shown) can be applied over the source-level insulating layer 8. The photoresist layer can be lithographically patterned to form discrete openings over the area of the source layer 10 and over portions of the electrically conductive layers 46 that do not underlie any other electrically conductive layer 46 (i.e., in a staircase portion of the contact region 300). An anisotropic etch process can be performed to etch through unmasked portions of the source-level insulating layer 8, the insulating layers 32, and the dielectric material layers 41 selective to the materials of the electrically conductive layers 46 and the source layer 10. At least one source contact cavity is formed on a backside (i.e., the distal side) of the source layer 10, and layer contact via cavities are formed through the source-level insulating layer 8 and a respective subset of layers among the insulating layers 32 and the dielectric material layers 41. The electrically conductive layers 46 in the staircase portion of the contact region 300 act as etch stop layers during formation of the layer contact via cavities. The photoresist layer can be subsequently removed, for example, by ashing.

At least one conductive fill material can be deposited in the at least one source contact cavity and the layer contact via cavities. For example, the at least one conductive fill material may comprise a metallic barrier liner material (such as TiN, TaN, WN, MoN, TiC, TaC, WC, etc.) and a metallic fill material (such as W, Ti, Ta, Co, Ru, Mo, Cu, etc.). Excess portions of the at least one conductive fill material located above the horizontal plane including the backside surface (i.e., the distal surface from the bonding interface 800) of the source-level insulating layer 8 can be removed by a planarization process. The planarization process may comprise a chemical mechanical polishing (CMP) process and/or a recess etch process. Each remaining portion of the at least one conductive fill material that fills a respective source contact cavity constitutes a source contact via structure 82. Each remaining portion of the at least one conductive fill material that fills a respective layer contact via cavity constitutes a layer contact via structure 86. Each of the electrically conductive layers 46 can be contacted by a respective layer contact via structure 86. Since the sidewalls of the conductive layer contact via structures 86 only contact dielectric materials (i.e., the insulating layers 32 and the dielectric material layers 41), an insulating sidewall spacer surrounding the structures 86 may be omitted.

Generally, contact via cavities (such as the layer contact via cavities) can be formed from underneath (i.e., from the side distal from the bonding interface 800) of the alternating stacks {32, (46, 41)} through a respective subset of the dielectric material layers 41 and through a respective subset of the insulating layers 32 onto a bottom (i.e., distal) surface of a respective one of the electrically conductive layers 46. The contact via cavities can be arranged as rows of contact via cavities formed within a respective repetition unit RU in a respective contact region 300. In one embodiment, the via-fill pillar structures (24, 26) can be arranged along the first horizontal direction hd1 within a uniform pitch p, and the contact via cavities can be arranged along the first horizontal direction hd1 with the uniform pitch p, and can be laterally offset from a row of the via-fill pillar structures (24, 26) (located within a row of access via cavities 29) along the second horizontal direction hd2. As such, the layer contact via structures 86 can be arranged along the first horizontal direction hd1 with the uniform pitch p, and can be laterally offset from the via-fill pillar structures (24, 26) along a second horizontal direction hd2.

In one embodiment, the source-level insulating layer 8 embeds the source layer 10. The layer contact via structures 86 vertically extend through the source-level insulating layer 8. In one embodiment, bottom surfaces (i.e., the distal surfaces) of the layer contact via structures 86 are located within a horizontal plane (which is herein referred to as a second horizontal plane HP2) including the bottom surface (i.e., the distal surface) of the source-level insulating layer 8. It is understood that the exemplary structure may be flipped upside down, and a top surface may become a bottom surface, and a bottom surface may become a top surface depending on the orientation of the exemplary structure.

The layer contact via structures 86 vertically extend through a respective subset of the dielectric material layers 41 in an alternating stack {32, (46, 41)}, and contact a bottom surface (i.e., a distal surface) of a respective one of the electrically conductive layers 46 in the alternating stack {32, (46, 41)}. In one embodiment, the layer contact via structures 86 are arranged along the first horizontal direction hd1 with a uniform pitch p; the via-fill pillar structures (24, 26) are arranged along the first horizontal direction hd1 with the uniform pitch p and are laterally offset from the contact via structures 86 along the second horizontal direction hd2; and each of the contact via structures 86 is laterally offset from a respective one of the via-fill pillar structures (24, 26) by a lateral offset distance lod.

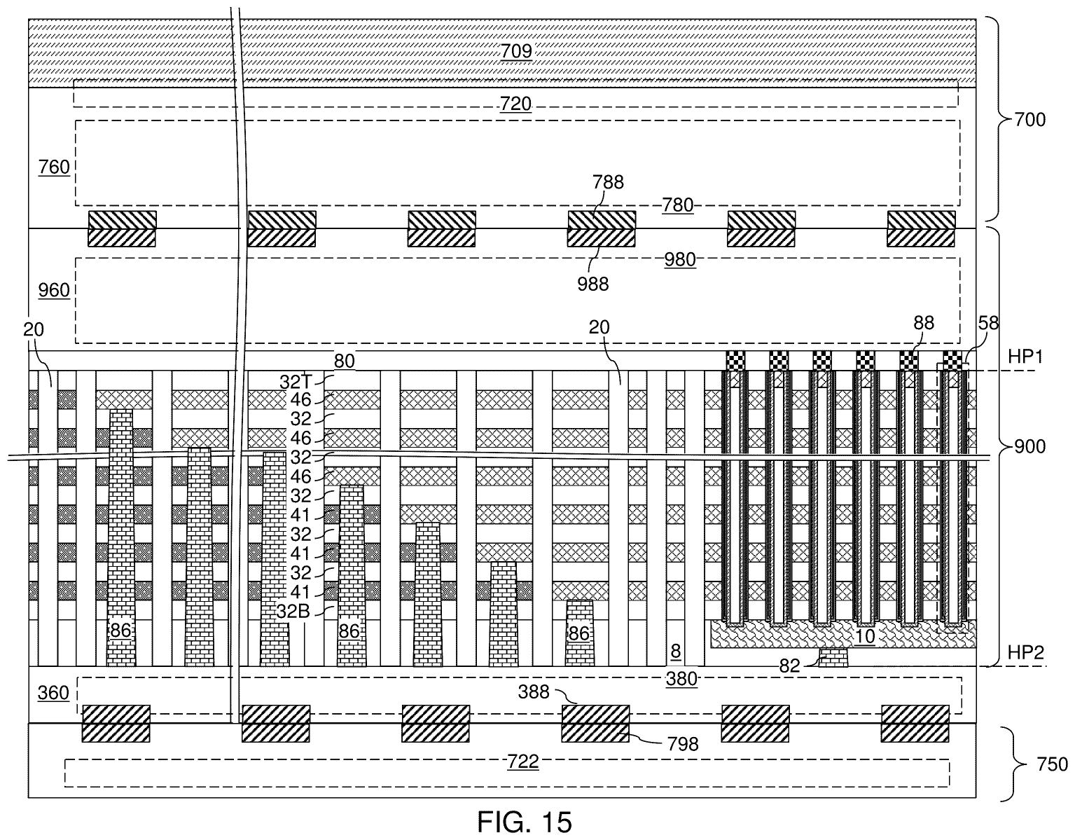

Referring to FIG. 15, backside dielectric material layers 360 can be formed on the distal surface (i.e., the backside surface) of the source-level insulating layer 8. Backside metal interconnect structures 380 are formed in the backside dielectric material layers 360. The backside metal interconnect structures 380 can be electrically connected to a respective one of the electrically conductive layers 46, the source layer 10, and various additional conductive via structures (not illustrated) that vertically extend through the insulating layers 32 and the dielectric material layers 41. For example, a first subset of the backside metal interconnect structures 380 can be electrically connected to a respective one of the layer contact via structures 86, and a second subset of the backside metal interconnect structures 380 can be electrically connected to the source layer 10. The backside metal interconnect structures 380 may comprise backside metal line structures and backside metal via structures. Backside bonding pads 388 may be formed on the backside (i.e., the distal side) of the backside dielectric material layers 360.

A second logic die 750 may be bonded to the backside bonding pads 388. The second logic die 750 includes a second a peripheral circuit 722 configured to control operation of the memory array within the memory die 900. For example, the second peripheral circuit 722 may comprise a word line driver circuit for driving the word lines 46 via the contact via structures 86, and a source bias circuit for biasing the source layer 10. The second logic die 750 includes second logic-side bonding pads 798 electrically bonded to the backside bonding pads 389.

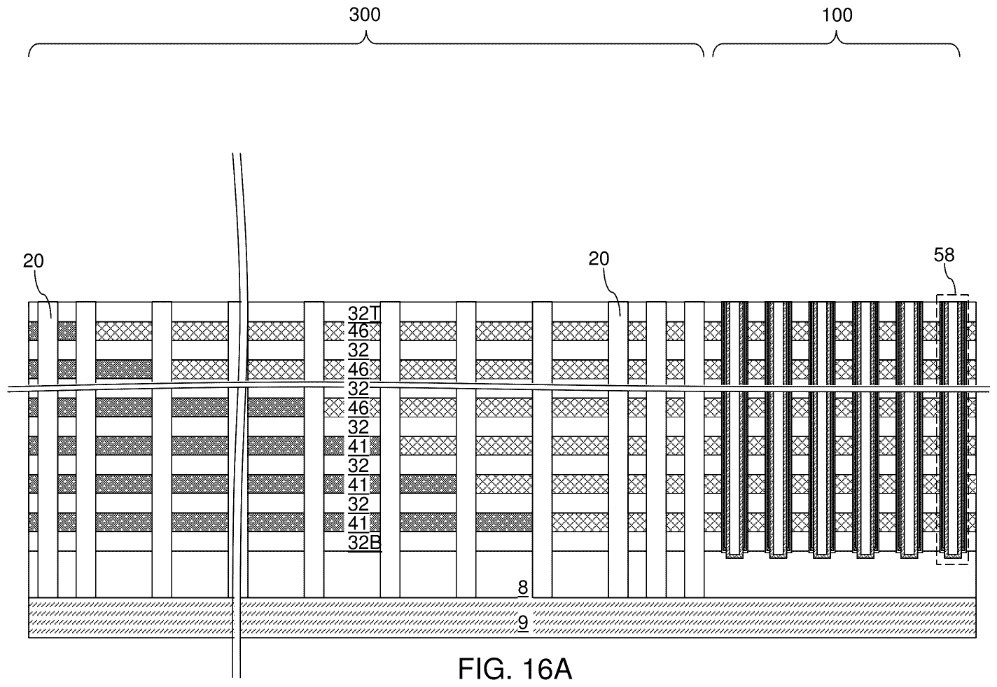

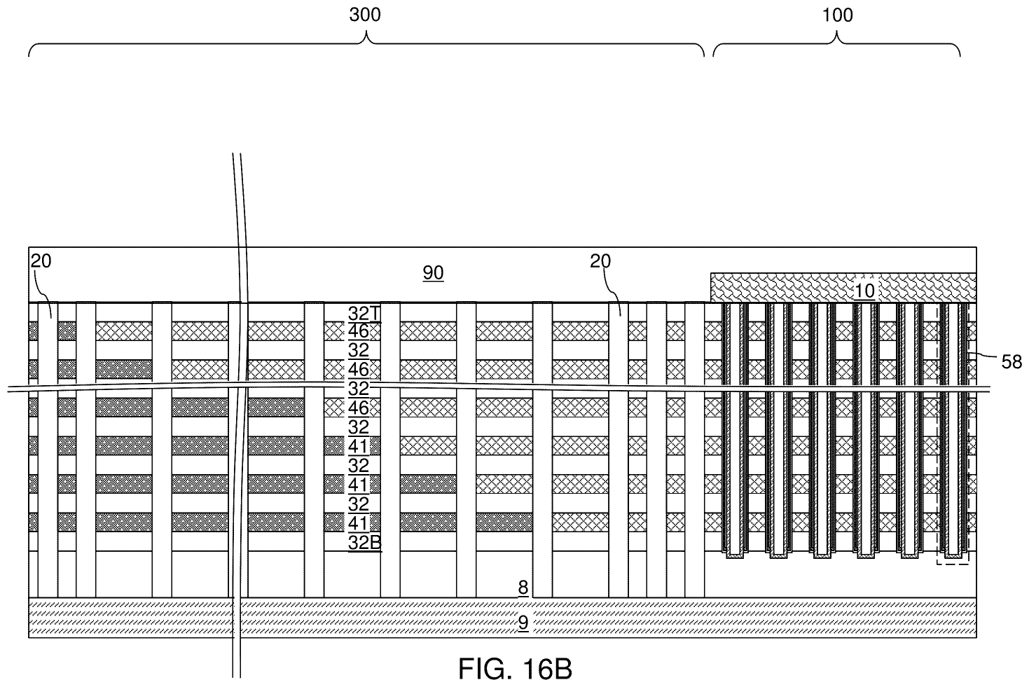

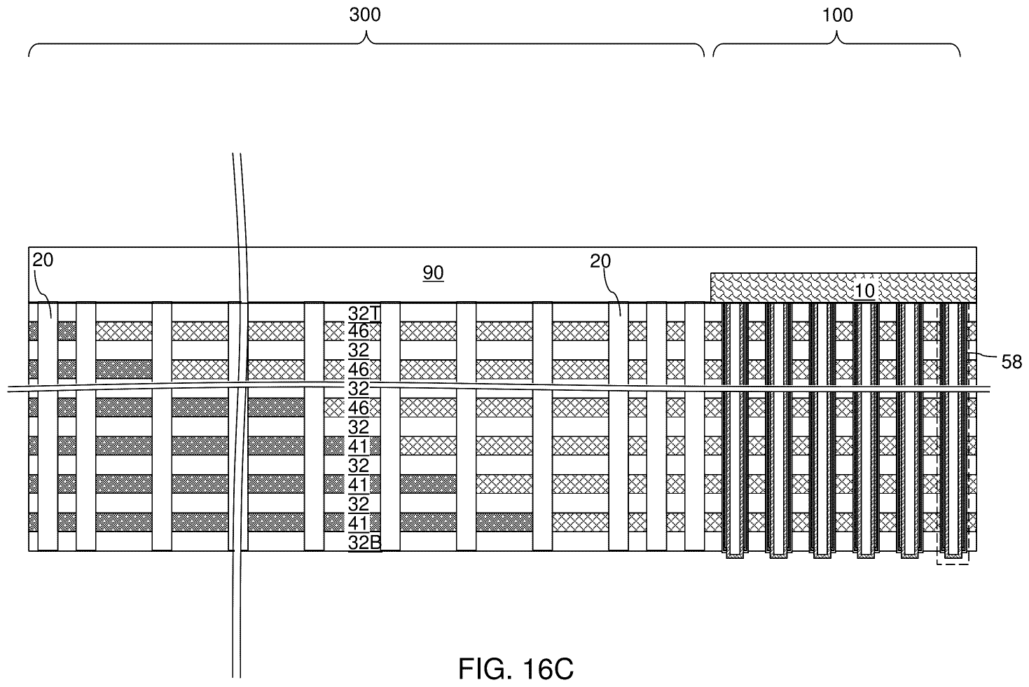

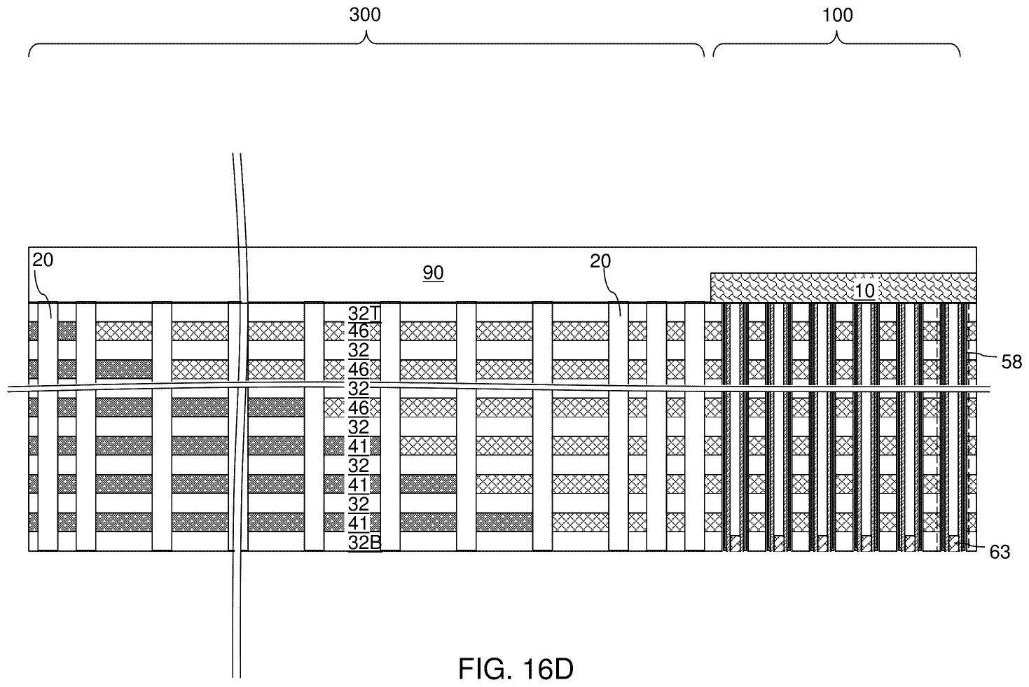

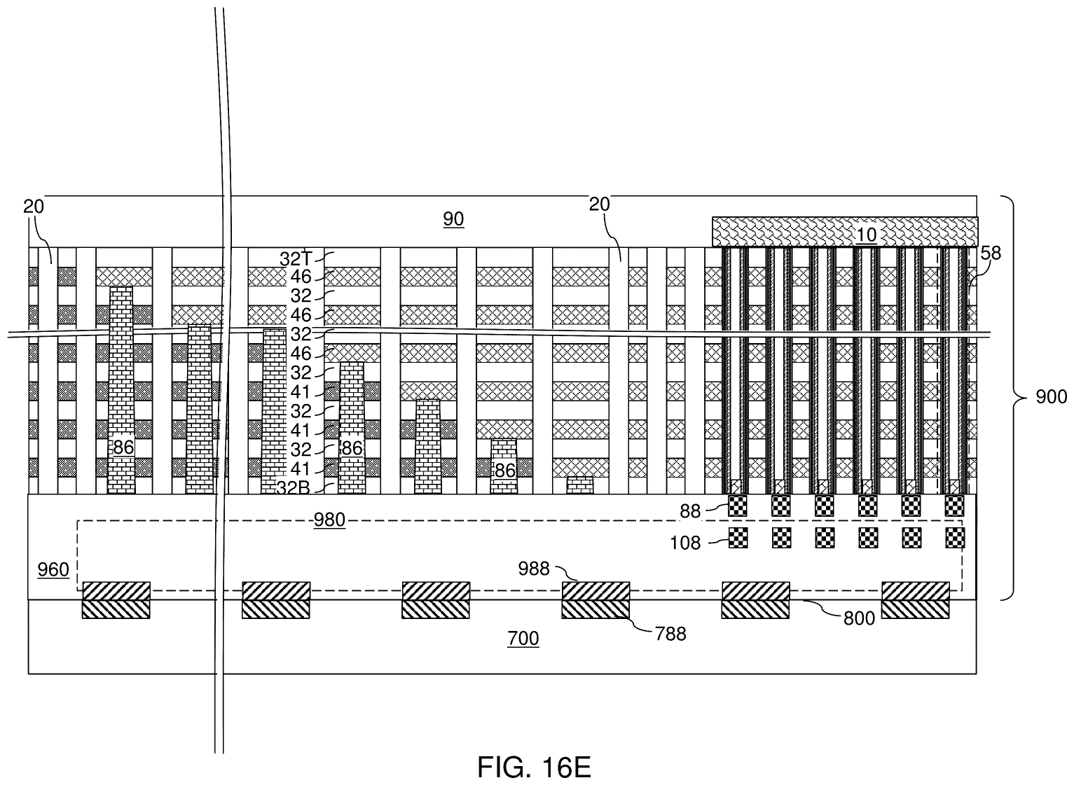

FIGS. 16A, 16B, 16C, 16D and 16E are sequential vertical cross-sectional views of steps during fabrication of an alternative exemplary structure according to an alternative embodiment of the present disclosure.

The alternative exemplary structure of FIG. 16A may be derived from the exemplary structure of FIG. 10D by omitting formation of the source layer 10 at the step shown in FIG. 1 and by omitting the steps shown in FIGS. 4E and 4F to omit recessing the dielectric core 62 and formation of the drain regions 63.

Referring to FIG. 16B, the source layer 10 is formed over the alternating stack {(32), (41,46)} and contact with the top ends of the vertical semiconductor channel regions 60 located in the memory opening fill structures 58. The source layer 10 may be formed by depositing at least one electrically conductive layer, such as a heavily doped semiconductor (e.g., polysilicon or amorphous silicon) layer and an optional metal or metal alloy capping layer, and optionally patterning the at least one electrically conductive layer, such that the source layer 10 remains at least in the memory array region 100. A capping dielectric layer 90, such as silicon oxide or silicon nitride layer, may be formed over the source layer 10.

Referring to FIG. 16C, the carrier substrate 9 and the insulating layer 8 are removed, as described above with respect to FIG. 13. A temporary handle substrate may be attached to the capping dielectric layer 90 for support during the removal of the carrier substrate 9 and the insulating layer 8.

Referring to FIG. 16D, the drain regions 63 are formed in contact with the vertical semiconductor channels 60 in the memory opening fill structures 58 using the steps described above with respect to FIGS. 4E and 4F. The drain regions 63 are formed in contact with the bottom ends of the vertical semiconductor channels 60 that become exposed after the removal of the carrier substrate 9 and the insulating layer 8. Thus, in the alternative embodiment, the source layer 10 and the drain regions 63 are formed on opposite ends of the memory opening fill structures 58 from their locations in the exemplary structure of the embodiment shown in FIGS. 13-15.

Referring to FIG. 16E, the drain contact via structures 88 are formed in contact with the drain regions 63 as described above with respect to FIG. 11. Subsequently, the memory-side dielectric layers 960, the memory-side interconnect structures 980 (including the bit lines 108) and the bonding pads 988 are formed over the drain regions 63 and the drain contact via structures 88, as described above with respect to FIG. 11. The logic die 700 is then bonded to the bonding pads 988 as described above with respect to FIG. 12.

In this alternative embodiment, the second logic die 750 may be omitted. In that case, the logic die includes both the bit line driver circuit and the word line driver circuit which are electrically connected to the word lines 46 and the bit lines 108, respectively. In the alternative exemplary structure of the embodiment of FIG. 16E, the electrically conductive layer 46 having the longest lateral length is located farther from the bonding interface 800 with the logic die 700 than the electrically conductive layer 46 having the shortest lateral length. In contrast, in the exemplary structure of the embodiment shown in FIG. 15, the electrically conductive layer 46 having the longest lateral length is located closer to the bonding interface 800 with the logic die 700 than the electrically conductive layer 46 having the shortest lateral length.

In the alternative exemplary structure of the embodiment of FIG. 16E, the lateral extents of the electrically conductive layers 46 in the alternating stack 32, (46, 41)} decrease with a vertical distance from a horizontal plane including an interface between the source layer 10 and the alternating stack {32, (46, 41)}. In contrast, in the exemplary structure of the embodiment shown in FIG. 15, the lateral extents of the electrically conductive layers 46 in the alternating stack 32, (46, 41)} increase with a vertical distance from a horizontal plane including an interface between the source layer 10 and the alternating stack {32, (46, 41)}.

Referring collectively to all embodiments of the present disclosure, a device structure comprises: an alternating stack {32, (46, 41)} of insulating layers 32 and composite layers (46, 41) located over a source layer 10, wherein each of the composite layers (46, 41) includes a combination of a respective dielectric material layer 41 and a respective electrically conductive layer 46; memory openings 49 vertically extending through the alternating stack {32, (46, 41)}; memory opening fill structures 58 located in the memory openings 49, wherein each of the memory opening fill structures 58 comprises a respective vertical stack of memory elements (e.g., portions of the memory film 50) and a respective vertical semiconductor channel 60; and contact via structures 86 vertically extending through a respective subset of the dielectric material layers 41 and the insulating layers 32 in the alternating stack {32, (46, 41)} and contacting a horizontal surface of a respective one of the electrically conductive layers 46 in the alternating stack {32, (46, 41)}.

In the exemplary structure of the embodiment shown in FIG. 15, the lateral extents of the electrically conductive layers 46 in the alternating stack 32, (46, 41)} increase with a vertical distance from a horizontal plane including an interface between the source layer 10 and the alternating stack {32, (46, 41)}. In contrast, in the alternative exemplary structure of the embodiment of FIG. 16E, the lateral extents of the electrically conductive layers 46 in the alternating stack 32, (46, 41)} decrease with a vertical distance from a horizontal plane including an interface between the source layer 10 and the alternating stack {32, (46, 41)}.

In the embodiment of FIG. 15, the lateral extents of the dielectric material layers 41 decrease with the vertical distance from the horizontal plane including the interface between the source layer 10 and the alternating stack {32, (46, 41)}. In contrast, in the alternative embodiment of FIG. 16E, the lateral extents of the dielectric material layers 41 increase with the vertical distance from the horizontal plane including the interface between the source layer 10 and the alternating stack {32, (46, 41)}.

In one embodiment, the device structure comprises via-fill pillar structures (24, 26) vertically extending through a respective subset of the electrically conductive layers 46, having top surfaces within a first horizontal plane HP1, and having bottom surfaces at different vertical distances from the first horizontal plane HP1. In one embodiment, the contact via structures 86 are arranged along a first horizontal direction hd1 with a uniform pitch p; the via-fill pillar structures (24, 26) are arranged along the first horizontal direction hd1 with the uniform pitch p and are laterally offset from the contact via structures 86 along a second horizontal direction hd2; and each of the contact via structures 86 is laterally offset from a respective one of the via-fill pillar structures (24, 26) by a lateral offset distance lod. In one embodiment, each of the dielectric material layers 41 comprises a sidewall segment that is equidistant from a periphery of a respective one of the via-fill pillar structures (24, 26).

In one embodiment, the device structure comprises: lateral isolation trenches 79 vertically extending through each of the composite layers (46, 41) within the alternating stack {32, (46, 41)} and laterally extending along a first horizontal direction hd1; and lateral isolation trench fill structures (74, 76) located in a respective one of the lateral isolation trenches 79, wherein each of the lateral isolation trench fill structures (74, 76) and the via-fill pillar structures (24, 26) comprises a same set of at least one fill material that includes an insulating fill material. In one embodiment, the device structure comprises support wall structures 120 in contact with a respective subset of the lateral isolation trench fill structures (74, 76) and in contact with interfaces between a respective insulating layer 32 and a respective electrically conductive layer 46 in the composite layers (46, 41) and vertically extending through each layer within the alternating stack {32, (46, 41)}.

In one embodiment, the device structure also includes memory-side dielectric material layers 960 overlying the alternating stack {32, (46, 41)}; and memory-side metal interconnect structures 980 including bit lines 108 and memory-side bonding pads 988 embedded within the memory-side dielectric material layers 960. In one embodiment, the device structure also includes a first logic die 700 comprising first logic-side bonding pads 788 electrically bonded to the memory-side bonding pads 988.

In the embodiment of FIG. 15, backside dielectric material layers 380 are located underneath the source layer 10 and embed backside metal interconnect structures 380 and backside bonding pads 388. A first subset of the backside metal interconnect structures 380 is electrically connected to a respective one of the contact via structures 86 and a second subset of the backside metal interconnect structures 380 is electrically connected to the source layer 10. In the embodiment of FIG. 15, the device structure also includes a second logic die 750 comprising second logic-side bonding pads 798 electrically bonded to the backside bonding pads 388. The first logic die comprises a bit line driver circuit 720 which is electrically connected to the bit lines 108; and the second logic die 750 comprises a word line driver circuit 722 which is electrically connected to the electrically conductive layers 46 through the contact via structures 86.

In the alternative embodiment of FIG. 16E, the first logic die 700 comprises a bit line driver circuit 720 which is electrically connected to the bit lines 108, and a word line driver circuit 720 which is electrically connected to the electrically conductive layers 46 through the contact via structures 86.

The various embodiments of the present disclosure provide layer contact via structures 86 to an inverted staircase in electrically conductive layers 46. The layer contact via structures 86 extend through an alternating stack of insulating layers 32 and dielectric material layers 41. Thus, a large retro-stepped dielectric layer (e.g., silicon oxide layer) does not have to be formed over the steps of a staircase portion of the contact region 300. By omitting the retro-stepped dielectric layer, subsidence of the device layers is reduced, a high cost large area planarization of the retro-stepped dielectric layer is omitted, and cryogenic reactive ion etching may be used to form the support openings and memory openings through the alternating stack. In contrast, the use of cryogenic reactive ion etching to form openings through the retro-stepped dielectric layer is relatively difficult. Furthermore, the chance of bowing of the backside trenches 79 resulting in undesirable contact between the support pillar structures 20 and the backside trenches, and lateral deflection and vertical subsidence of the electrically conductive layers 46 is reduced with the inverted staircase.

Although the foregoing refers to particular preferred embodiments, it will be understood that the claims are not so limited. It will occur to those of ordinary skill in the art that various modifications may be made to the disclosed embodiments and that such modifications are intended to be within the scope of the claims. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the claims may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

1. A device structure, comprising:
an alternating stack of insulating layers and composite layers located over a source layer, wherein each of the composite layers includes a combination of a respective dielectric material layer and a respective electrically conductive layer;
memory openings vertically extending through the alternating stack;
memory opening fill structures located in the memory openings, wherein each of the memory opening fill structures comprises a respective vertical stack of memory elements and a respective vertical semiconductor channel; and
contact via structures vertically extending through a respective subset of the dielectric material layers and the insulating layers in the alternating stack and contacting a horizontal surface of a respective one of the electrically conductive layers in the alternating stack.

2. The device structure of claim 1, wherein:
lateral extents of the electrically conductive layers in the alternating stack increase with a vertical distance from a horizontal plane including an interface between the source layer and the alternating stack; and
lateral extents of the dielectric material layers decrease with the vertical distance from the horizontal plane including the interface between the source layer and the alternating stack.

3. The device structure of claim 1, wherein:
lateral extents of the electrically conductive layers in the alternating stack decrease with a vertical distance from a horizontal plane including an interface between the source layer and the alternating stack; and
lateral extents of the dielectric material layers increase with the vertical distance from the horizontal plane including the interface between the source layer and the alternating stack.

4. The device structure of claim 1, further comprising via-fill pillar structures vertically extending through a respective subset of the electrically conductive layers, having top surfaces within a first horizontal plane, and having bottom surfaces at different vertical distances from the first horizontal plane.

5. The device structure of claim 4, wherein:
the contact via structures are arranged along a first horizontal direction with a uniform pitch;
the via-fill pillar structures are arranged along the first horizontal direction with the uniform pitch and are laterally offset from the contact via structures along a second horizontal direction perpendicular to the first horizontal direction; and
each of the contact via structures is laterally offset from a respective one of the via-fill pillar structures by a lateral offset distance.

6. The device structure of claim 4, wherein each of the dielectric material layers comprises a sidewall segment that is equidistant from a periphery of a respective one of the via-fill pillar structures.

7. The device structure of claim 5, further comprising:
lateral isolation trenches vertically extending through each of the composite layers within the alternating stack and laterally extending along a first horizontal direction; and
lateral isolation trench fill structures located in a respective one of the lateral isolation trenches, wherein each of the lateral isolation trench fill structures and the via-fill pillar structures comprises a same set of at least one fill material that includes an insulating fill material.

8. The device structure of claim 7, further comprising support wall structures in contact with a respective subset of the lateral isolation trench fill structures and in contact with interfaces between a respective insulating layer and a respective electrically conductive layer in the composite layers and vertically extending through each layer within the alternating stack.

9. The device structure of claim 1, further comprising:
memory-side dielectric material layers overlying the alternating stack; and
memory-side metal interconnect structures including bit lines and memory-side bonding pads embedded within the memory-side dielectric material layers.

10. The device structure of claim 9, further comprising a first logic die comprising first logic-side bonding pads electrically bonded to the memory-side bonding pads.

11. The device structure of claim 10, further comprising backside dielectric material layers located underneath the source layer and embedding backside metal interconnect structures and backside bonding pads, wherein a first subset of the backside metal interconnect structures is electrically connected to a respective one of the contact via structures and a second subset of the backside metal interconnect structures is electrically connected to the source layer.

12. The device structure of claim 11, further comprising a second logic die comprising second logic-side bonding pads electrically bonded to the backside bonding pads.

13. The device structure of claim 12, wherein:
the first logic die comprises a bit line driver circuit which is electrically connected to the bit lines; and
the second logic die comprises a word line driver circuit which is electrically connected to the electrically conductive layers through the contact via structures.

14. The device structure of claim 10, wherein the first logic die comprises a bit line driver circuit which is electrically connected to the bit lines, and a word line driver circuit which is electrically connected to the electrically conductive layers through the contact via structures.

15. A method of forming a device structure, comprising:
forming an alternating stack of insulating layers and sacrificial material layers comprising a dielectric material over carrier substrate;
forming memory openings through the alternating stack;
forming memory opening fill structures in the memory openings, wherein each of the memory opening fill structures comprises a respective vertical stack of memory elements and a respective vertical semiconductor channel;
forming lateral isolation trenches and access via cavities in the alternating stack, wherein each of the sacrificial material layers is exposed to each of the lateral isolation trenches, and the access via cavities have different depths;
forming lateral recesses by isotropically recessing the sacrificial material layers around the lateral isolation trenches and the access via cavities, wherein the lateral extents of the lateral recesses are different, and wherein remaining portions of the sacrificial material layers comprise dielectric material layers;
forming electrically conductive layers in the lateral recesses;
forming lateral isolation trench fill structures and via-fill pillar structures in the lateral isolation trenches and the access via cavities, respectively;
forming contact via cavities through a respective subset of the dielectric material layers and through a respective subset of the insulating layers onto a horizontal surface of a respective one of the electrically conductive layers; and
forming contact via structures in the contact via cavities in contact with the electrically conductive layers.

16. The method of claim 15, further comprising forming a source layer is contact with the memory opening fill structures.

17. The method of claim 16, wherein:
the source layer is formed on or above the carrier substrate; and
the method further comprises removing the carrier substrate, wherein the contact via cavities are formed after removal of the carrier substrate.

18. The method of claim 16, wherein:
the alternating stack is formed over a carrier substrate;
the source layer is formed on the alternating stack; and
the method further comprises removing the carrier substrate after forming the source layer.

19. The method of claim 15, wherein:
the access via cavities are arranged along a first horizontal direction within a uniform pitch; and
the contact via cavities are arranged along the first horizontal direction with the uniform pitch and is laterally offset from the access via cavities along a second horizontal direction perpendicular to the first horizontal direction.

20. The method of claim 15, further comprising forming support wall structures comprising an insulating material through the alternating stack,
wherein:
the lateral isolation trenches and the access via cavities are formed on opposite sides of the support wall structures;
each of the support wall structures comprises a section that is perpendicular to a lengthwise direction of the lateral isolation trenches;
each of the support wall structures is intersected by a respective pair of the lateral isolation trenches; and
the lateral recesses are formed by performing an isotropic etch process that isotropically recesses the sacrificial material layers selective to the insulating material of the support wall structures.
